(19) United States
(12) Patent Application Publication
(10) Pub. No.: US 2007/0090756 A1
(43) Pub. Date: Apr. 26, 2007

(54) Organic electroluminescent element

(75) Inventors: Hisashi Okada, Kanagawa (JP); Nobuhiro Nishita, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 11/544,669

(22) Filed: Oct. 10, 2006

(30) Foreign Application Priority Data
Oct. 11, 2005 (JP) 2005-296704

(51) Int. Cl. H01L 51/50

(52) U.S. Cl. 313/506; 428/690; 428/917; 313/504

(57) ABSTRACT

The invention provides an organic electroluminescent element comprising an organic layer containing at least one luminescent layer and at least one charge transporting layer being interposed between a pair of electrodes, wherein the organic electroluminescent element comprises: (1) two or more kinds of host materials and at least one luminescent material contained in the luminescent layer; (2) at least one layer adjacent to the luminescent layer, the layer containing a host material and substantially no luminescent material; and (3) at least one charge transporting layer being doped with at least one of an electron-accepting compound and an electron-donating compound.

### CROSS-REFERENCE TO RELATED APPLICATIONS

This invention claims priority under 35 USC 119 from Japanese Patent Application No. 2005-296704, the disclosure of which is incorporated by reference herein.

### BACKGROUND OF THE INVENTION

1. Field of the Invention

The invention relates to an organic electroluminescent element (may be appropriately referred to as an organic EL element or an element hereinafter) that can be effectively used for surface light sources such as a full color display, a backlight and an illumination light source, and light source arrays of such as printers.

2. Description of the Related Art

The organic EL element comprises a luminescent layer or a plural organic compound layer including the luminescent layer, and a pair of opposite electrodes with interposition of the organic compound layer. Electrons injected from a cathode and holes injected from an anode are recombined in the organic compound layer of the organic EL element, and a light is emitted from the element by taking advantage of light emission from excitons formed by recombination, and/or light emission from excitons of other molecules formed by energy transfer from the excitons formed by recombination.

Luminance and element efficiency of organic EL elements have been largely improved by forming a laminated structure having different functions in respective layers. For example, frequently used elements include a dual-layer laminated element having a hole transport layer and a layer that serves as both a luminescent layer and electron transport layer, a three-layer laminated element having a hole transport layer, a luminescent layer and an electron transport layer, and a four-layer laminated element comprising a hole transport layer, a luminescent layer, a hole blocking layer and an electron transport layer (for example, see Science, Vol. 267, No. 3, 1995, p1332 1).

However, practical application of the organic EL element yet involves many problems to be solved. In particular, the largest problem is deterioration of the quality during continuous driving, or incidence and growth of non-luminescent or low luminance regions (so-called dark spots).

A method proposed for preventing deterioration of luminance during driving is to eliminate interfaces of the organic layer in the element by providing a mixed region of a hole transport material and an electron transport material (see, for example, Japanese Patent Application Laid-Open (JP-A) No. 2002-305085). Deterioration of luminance is prevented by this method by suppressing electric charges from accumulating at the interface during driving by eliminating the interface between the organic layers in the element. However, the holes leaking out of the mixed region may be injected into the electron transport material, or the electrons leaking out of the mixed region may be injected into the hole transport material at the interface of the region adjacent to the mixed region. Accordingly, it may be apprehended that deterioration of the hole transport material from an anionic state or deterioration of the electron transport material from a cationic state may be caused.

JP-A No. 2004-6287 disclosed a blue phosphorescent element by focusing a difference of the energy level of LUMO (lowest unoccupied molecular orbit) and a difference of the energy level of HOMO (highest occupied molecular orbit) between the hole blocking layer and luminescent layer, and the relation of the band gap and molecular weight of the host compound. However, luminous efficiency and driving durability of the blue phosphorescent element disclosed in the patent publication are not so sufficiently high.

The luminescent layer of the blue phosphorescent element contains a blue phosphorescent material and a host material. The blue phosphorescent material usually has 272 kJ/mol (65 kcal/mol) or more of lowest excited triplet energy (may be appropriately referred to “T₁ energy” hereinafter). Accordingly, while a host material having 272 kJ/mol (65 kcal/mol) or more of T₁ energy is necessary for attaining a high luminous efficiency, charges (holes or electrons) are hardly injected into the host material having 272 kJ/mol (65 kcal/mol) or more of T₁ energy. Consequently, the blue phosphorescent element involved the problems of poor driving durability and high driving voltage.

While JP-A No. 2001-223084 has disclosed a luminescent element doped with an electron-accepting compound in the hole transport layer for lowering the driving voltage, the element does not correspond to the host material having a high T₁ energy with insufficient luminous efficiency.

As hitherto described, it is the reality that a blue phosphorescent element with both high luminous efficiency and driving durability, and with a low driving voltage is not available today.

### SUMMARY OF THE INVENTION

The invention has been made in view of the above circumstances and provides an organic electroluminescent element.

A first aspect of the invention provides an organic electroluminescent element including, interposed between a pair of electrodes, an organic layer including at least one luminescent layer and at least one charge transporting layer, wherein the organic electroluminescent element comprises:

(1) two or more kinds of host materials and at least one luminescent material included in the luminescent layer;

(2) at least one layer that is adjacent to the luminescent layer and includes a host material and substantially no luminescent material; and

(3) at least one charge transporting layer being doped with at least one of an electron-accepting compound or an electron-donating compound.

### DETAILED DESCRIPTION

The object of the invention is to provide an organic electroluminescent element with high luminous efficiency and driving durability, and with a low driving voltage.

The organic EL element of the invention has at least one luminescent layer and an intermediate layer that is adjacent to the luminescent layer and substantially includes only a host material, and at least one charge transport layer is doped with at least one of an electron-accepting compound or an electron-donating compound.

In a preferable aspect of the invention, the charge transport layer is a hole transport layer disposed between the luminescent layer and an anode, and the hole transport layer is doped with a p-dopant of an electron-accepting compound.

In another preferable aspect of the charge transport layer of the invention, the charge transport layer is an electron transport layer disposed between the luminescent layer and a cathode, and the electron transport layer is doped with an n-type dopant of electron-donating compound.

In a preferable aspect of the invention, the intermediate layer substantially including only the host material is a hole transporting intermediate layer and disposed on the surface of the luminescent layer that faces an anode, and includes a hole transporting host material.

In another preferable aspect of the invention, the intermediate layer substantially including only the host material is an electron transporting intermediate layer and disposed on the surface of the luminescent layer that faces a cathode, and includes an electron transporting host material.

The phrase “substantially including only the host material” as used in the invention means that the luminescent material is not included to an extent that serves for light emission.

When the ionization potential of the luminescent material is represented by Ip(D) and the minimum of the ionization potential of the plural host material is represented by Ip(H)min, ΔIp defined by ΔIp=Ip(D)−Ip(H)min preferably satisfies the relation of ΔIp>0 eV in the organic electroluminescent element of the invention.

When the electron affinity of the luminescent material is represented by Ea(D) and the maximum of the electron affinity of the plural host material is represented by Ea(H)max, ΔEa defined by ΔEa=Ea(H)max−Ea(D) preferably satisfies the relation of ΔEa>0 eV.

More preferably, ΔIp satisfies the relation of ΔIp>0 eV and ΔEa satisfied the relation of ΔEa>0 eV in the organic electroluminescent element.

It is preferable for the organic electroluminescent element of the invention that ΔIp satisfied the relation of 1.2 eV>ΔIp>0.2 eV and/or ΔEa satisfies the relation of 2 eV>ΔEa>0.2 eV from the standpoint of driving durability, It is particularly preferable that ΔIp satisfied the relation of 1.2 eV>ΔIp>0.4 eV and/or ΔEa satisfies the relation of 1.2 eV>ΔEa>0.4 eV

When the organic electroluminescent element of the invention satisfies the above-mentioned conditions, the driving voltage may be decreased by reducing the injection barrier of the carrier into the luminescent layer, while the luminescent material may be suppressed from being deteriorated with the carrier by injecting the carrier mainly into the host material. Consequently, durability of the electroluminescent material may be improved.

Ip(H)min is preferably 5.1 eV or more to 6.3 eV or less, more preferably 5.4 eV or more to 6.1 eV or less, and further preferably 5.6 eV or more to 5.8 eV or less in the organic electroluminescent element of the invention.

Ea(H)max is preferably 2.6 eV or more to 3.3 eV or less, more preferably 2.8 eV or more to 3.2 eV or less, and further preferably 2.8 eV or more to 3.1 eV or less in the organic electroluminescent element of the invention.

It is particularly preferable that Ip(H)min is 5.6 eV or more to 5.8 eV or less, and Ea(H)max is 2.8 eV or more to 3.1 eV or less.

An effect obtained by satisfying such conditions is that low voltage driving is possible since injection of the holes and/or injection of electrons from the hole transporting intermediate layer and/or electron transporting intermediate layer can easily occur.

Another effect is that interaction between the plural host materials in the luminescent layer may be suppressed. When a charge transfer complex having a lower excitation energy state, or an exiplex, is formed as a result of interaction between plural host materials, an excitation state that would naturally be formed in any of the host materials is formed on the charge transfer complex or exiplex, or the energy once formed on the host material is transferred from the excitation state to the charge transfer complex or exiplex. As a result, energy transfer to the luminescent material becomes insufficient, making it impossible to emit the prescribed light. Alternatively, a decrease in driving durability may occur due to decomposition from the excitation state on the charge transfer complex or exiplex.

Whether the plural host materials interact with one another in the luminescent layer or not may be judged by depositing single layer films comprising only each of the plural host materials of the luminescent layer under the same condition as depositing the luminescent layer. By measuring the fluorescence-phosphorescence spectrum of the single layer films of the host materials, and comparing the emission spectrum of each single host material with the emission spectrum of the film of the mixed host materials the existence or not of interaction can be determined.

In other words, the host materials are considered to interact with one another when long wavelength emission spectra that cannot be assigned to respective emission spectra belonging to the plural host material are observed in the fluorescent-phosphorescent spectra. It is particularly preferable that no emission spectra are observed in the long wavelength side 15 nm or longer than the wavelength of main peaks of respective emission spectra of the plural host material.

A spectrophotometer (trade name: RF-5300PC, manufactured by Shimadzu Corporation) may be used for measuring the fluorescence-phosphorescence spectra, where a light at a wavelength that is absorbed by each host material is used as an excitation light.

Hereinafter, the ionization potential Ip), electron affinity (Ea) and triplet state level (T₁) will be described.

The ionization potential Ip), electron affinity (Ea) and triplet state level (T₁) are obtained from the measurement of a single layer film prepared by depositing each material on quartz.

The ionic potential (Ip) is defined by a measured value at room temperature under an atmospheric pressure using a UV photoelectron analyzer (trade name: AC-1 or AC-2, manufactured by Riken Keiki Co. Ltd.). The measuring principle of the UV photoelectron analyzer is described in “Data Sheet of Work Function of Organic Thin Film”, by Chihaya Adachi et al., CMC Publishing Co., 2004.

The electron affinity (Ea) is defined as a value obtained by calculating the band gap from the long wavelength end of the absorption spectrum of the single layer film and calculating the electron affinity (Ea) from the values of the calculated band gap and the above ionization potential.

The lowest triplet excitation energy (triplet state level T₁) is defined by a value calculated from a short wavelength end after measuring the phosphorescence emission spectra at room temperature. The measuring temperature may be at a temperature cooled with liquid nitrogen.

The factors for reducing the driving voltage in the luminescent element of the invention are supposed as follows.

When a hole transporting intermediate layer comprising only a hole transporting host material is provided between the hole transport layer and luminescent layer, there is no difference of Ip between the material of the hole transporting intermediate layer and the hole transporting host material in the luminescent layer. Consequently, low voltage drive is possible since injection of the hole is facilitated due to reduced barrier for injecting the hole into the luminescent layer.

Likewise, when an electron transporting intermediate layer comprising only an electron transporting host material is provided between the electron transport layer and luminescent layer, there is no difference of Ea between the material of the electron transporting intermediate layer and the electron transporting host material in the luminescent layer. Consequently, low voltage drive is possible since injection of the electron is facilitated due to reduced barrier for injecting the electron into the luminescent layer.

Low voltage drive is also supposed to be possible by doping an electron-accepting dopant in the hole transport layer, since hole injection barrier from the anode to the hole transport layer can be reduced. Likewise, Low voltage drive is also supposed to be possible by doping an electron-donating dopant in the electron transport layer, since electron injection barrier from the cathode to the electron transport layer can be reduced.

The following light emission mechanism is conjectured to work with respect to evidently excellent driving durability of the luminescent element of the invention.

In other words, most of the holes injected from the anode are injected into the hole transporting host material in the luminescent layer via the hole injecting layer and hole transport layer. On the other hand, most of the electrons injected from the cathode are injected into the electron transporting host material in the luminescent layer via the electron injecting layer and electron transport layer. The holes are injected into HOMO of the electron transporting host material from the hole transporting host in the luminescent layer, and excitons are formed on the electron transporting host material. The electrons are injected into LUMO of the hole transporting host material from the electron transporting host material, and excitons are formed on the hole transporting host material. The energy of the excitation state of the host material is transferred to the luminescent material, and a light is emitted from the singlet and/or triplet state of the luminescent material.

The holes are mainly injected into the hole transporting host material while the electrons are mainly injected into the electron transporting host material when the holes and electrons are injected into the luminescent layer. Consequently, the hole transporting host material may be released from an anionic state while the electron transporting host material may be released from a cationic state to consequently enable driving durability to be improved. Since HOMO and LUMO of the luminescent material are outside of Ip(H)min and Ea(H)max, respectively, formed by the hole transporting host material and electron transporting host material, respectively, when the holes and electrons are injected into the luminescent layer, carriers are scarcely injected into the luminescent material. Accordingly, the luminescent material having low durability to cations and anions may be suppressed from being deteriorated to enable durability of the material to be improved.

Another factor that the luminescent element of the invention is remarkably excellent in driving durability is supposed as follows.

Injection of the hole from the anode to the hole transport layer can easily occur by doping an electron-accepting dopant into the hole transport layer, while injection of the hole into the luminescent layer can easily occur by providing a hole transporting intermediate layer comprising only the hole transporting host between the hole transport layer and luminescent layer. Consequently, the hole is hardly concentrated at the interface and deterioration of the element can be suppressed.

Likewise, injection of the electron from the cathode to the electron transport layer can easily occur by doping an electron-donating dopant into the electron transport layer, while injection of the electron into the luminescent layer can easily occur by providing an electron transporting intermediate layer comprising only the electron transporting host between the electron transport layer and luminescent layer. Consequently, the electron is hardly concentrated at the interface as compared with a structure in which the electron transport layer is in direct contact with the luminescent layer, and deterioration of the element can be suppressed.

While such effect for suppressing the carrier from being concentrated at the interface may be exhibited by providing a mixed layer, in which the hole transport material and electron transport material are mixed in a giving proportion, in the layer adjacent to the luminescent layer as disclosed in JP-A No. 2002-313584, the following problem arises by this structure. One problem is that the carrier is liable to leak from the luminescent layer, and luminous efficiency decreases due to decrease in recombination probability between the hole and electron. This phenomenon is conjectured to arise because the hole is liable to leak due to the presence of the hole transporting material having small Ip at the cathode side adjacent to the luminescent layer, and the electron is liable to leak due to the presence of the electron transporting material at the anode side adjacent to the luminescent layer.

On the contrary, both the hole and electron hardly leak from the luminescent layer in the invention, since the electron transporting material having large Ip (low HOMO) is present at the cathode side adjacent to the luminescent layer, while the hole transporting material having small Ea (high LUMO) is present at the cathode side adjacent to the luminescent layer. This structure permits recombination probability between the hole and electron to be high in the luminescent layer to enable the luminous efficiency to be high.

Another factor that the luminescent element of the invention is excellent in driving durability is conjectured as follows. While it is preferable that the luminescent layer of the luminescent element of the invention includes the electron transporting host material and hole transporting host material, the luminescent element may be deteriorated during driving due to excess injection of charges into the host material or luminescent material when the numbers of the holes and electrons are extremely unbalanced, and driving durability may be deteriorated. In other words, when the amount of injection of the hole is overwhelmingly larger as compared with the amount of injection of the electron, the electron transporting host material or luminescent material is deteriorated from its cationic state due to injection of a part of the holes into the layer, and driving durability is conjectured to be impaired. Likewise, when the amount of injection of the electron overwhelms the amount of injection of the hole, the hole transporting host material or luminescent material is deteriorated from its anionic state due to injection of a part of the electrons into the layer, and driving durability is conjectured to be impaired. However, the balance of charge injection into the luminescent layer can be controlled by doping the charge into the charge transfer layer in the element of the invention, and driving durability is conjectured to be further improved.

The organic electroluminescent element of the invention will be described in detail below.

(Structure)

The organic electroluminescent element of the invention has an organic compound layer comprising at least a luminescent layer between a pair of electrodes (anode and cathode) in addition to a hole transport layer between the anode and luminous layer and an electron transport layer between the cathode and luminescent layer.

At least one electrode of the pair of the electrodes is preferably transparent in view of the property of the luminescent element.

The laminated structure of the organic compound layer preferably comprises a hole transport layer, a luminescent layer and an electron transport layer laminated from the anode side. In addition, the laminate comprises a hole transporting intermediate layer between the hole transport layer and luminescent layer, and/or an electron transporting intermediate layer between the luminescent layer and electron transport layer. A hole injecting layer may be provided between the anode and hole transport layer, and an electron injecting layer may be provided between the cathode and electron transport layer.

The organic compound layer of the electroluminescent element of the invention is favorably a laminate comprising, from the anode side in the following layer, (1) a hole injecting layer, a hole transport layer (may also serve as a hole injecting layer and hole transport layer) and a hole transporting intermediate layer, a luminescent layer, an electron transport layer and an electron injecting layer (may also serve as an electron transport layer and electron injecting layer), (2) a hole injecting layer, a hole transport layer (may also serve as a hole injecting layer and a hole transport layer), a luminescent layer, an electron transporting intermediate layer, an electron transport layer and an electron injecting layer (may also serve as an electron transport layer and electron injecting layer), or (3) a hole injecting layer, a hole transport layer (may also serve as a hole injecting layer and hole transport layer), a hole transporting intermediate layer, a luminescent layer, an electron transporting intermediate layer, an electron transport layer and an electron injecting layer (may also serve as an electron transport layer and electron injecting layer).

The hole transporting intermediate layer preferably has a function for enhancing injection of holes into the luminescent layer and/or ability for blocking electrons.

The electron transporting intermediate layer preferably has a function for enhancing injection of electrons into the luminescent layer and/or ability for blocking holes.

The hole transporting intermediate layer and/or electron transporting intermediate layer preferably has a function for blocking excitons generated in the luminescent layer.

For effectively expressing such functions as enhancement of injection of the holes, enhancement of injection of the electrons, blocking of the holes, blocking of the electrons and blocking of the excitons, the hole transporting intermediate layer and the electron transporting intermediate layer are preferably located adjacent to the luminescent layer. Each layer may be divided into a plurality of the second layers.

The factors constituting the luminescent element of the invention will be described in detail hereinafter.

The organic compound layer of the invention is described below.

The organic electroluminescent element of the invention comprises the organic compound layer containing at least one luminescent layer. Examples of the organic compound layer other than the luminescent layer include the hole injecting layer, hole transport layer, hole transporting intermediate layer, luminescent layer, electron transporting intermediate layer, electron transport layer and electron injecting layer as described above.

(Deposition of Organic Compound Layer)

The each layer constituting the organic compound layer of the organic electroluminescent layer of the invention may be favorably formed by a dry deposition method such as vacuum deposition method or sputtering method, transcription method, printing method, coating method, ink jet method and spray method.

(Hole Injecting Layer, Hole Transport Layer)

The hole injecting layer and hole transport layer has a function for receiving the holes from the anode or anode side, and for transporting the holes to the cathode side.

Either inorganic compounds or organic compounds are available as the electron-accepting dopant introduced into the hole injecting layer or hole transport layer as long as the compound is an electron acceptable compound having a property for oxidizing organic compounds. Specific examples of the favorably used inorganic compound include metal halides such as ferric chloride, aluminum chloride, gallium chloride, indium chloride and antimony pentachloride, and metal oxides such as vanadium pentoxide and molybdenum trioxide.

Compounds having nitro group, halogen group, cyano group and trifluoromethyl group as substituents, quinone-based compounds, acid anhydride-based compounds and fulleren can be favorably used as the organic compound.

Specific examples of the organic compound include hexacyanobutadiene, hexacyanobenzene, tetracyanoethylene, tetracyanoquinodimethane, tetrafluoro tetracyanoquinodimethane, p-fluoranyl, p-chloranyl, p-bromanyl, p-benzoquinone, 2,6-dichlorobenzoquinone, 2,5-dichlorobenzoquinone, tetramethylbenzoquinone, 1,2,4,5-tetracyanobenzene, o-dicyanobenzene, p-dicyanobenzene, 1,4-dicyano-tetrafluorobenzene, 2,3-dichloro-5,6-dicyanobenzoquinone, p-dinitrobenzene, m-dinitrobenzene, o-dinitrobenzene, p-cyanonitrobenzene, m-cyanonitrobenzene, o-cyanonitrobenzene, 1,4-naphthoquinone, 2,3-dichloronaphthoquinone, 1-nitronaphthalene, 2-nitronaphthalene, 1,3-dinitronaphthalene, 1,5-dinitronaphthalene, 9-cyanoanthracene, 9-nitroanthracene, 9,10-anthraquinone, 1,3,6,8-tetranitrocarbazole, 2,4,7-trinitro-9-fluorenone, 2,3,5,6-tetracyanopyridine, maleic anhydride, phthalic anhydride, fullerene C60, fullerene C70, and compounds described in JP-A Nos.6-212153, 11-111463, 11-251067, 2000-196140, 2000-286054, 2000-3135580, 2001-102175, 2001-160493, 2002-252085, 2001-102175, 2001-160493, 2002-252085, 2002-56985, 2003-157981, 2003-271862, 2003-229278. 2004-342614, 2005-72012, 2005-166637 and 2005-209643.

The preferable compounds among the above-mentioned compounds are hexacyanobutadiene, hexacyanobenzene, tetracyanoethylene, tetracyanoquinodimethane, tetrafluoro tetracyanoquinodimethane, p-fluoranyl, p-chloranyl, p-bromanyl, p-benzoquinone, 2,6-dichlorobenzoquinone, 2,5-dichlorobenzoquinone, 1,2,4,5-tetracyanobenzene, 1,4-dicyano-tetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine or C60; and preferable compounds are hexacyanobutadiene, hexacyanobenzene, tetracyanoethylene, tetracyanoquinodimethane, tetrafluoro tetracyanoquinodimethane, p-fluoranyl, p-chloranyl, p-bromanyl, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone or 2,3,5,6-tetracyanopyridine with particularly preferable tetrafluoroquinodimethane.

One of these electron-accepting dopants may be used alone, or a combination of a plurality of the compounds may be used.

While the amount of use of the electron-accepting dopant varies depending on the kind of the material, the proportion is preferably in the range of 0.01% by mass to 50% by mass, more preferably 0.05% by mass to 20% by mass, and particularly preferably 0.1% by mass to 10% by mass, relative to the hole transport material. An amount of use of less than 0.01% by mass is not preferable with respect to the hole transport layer since the effect of the invention is not sufficiently manifested, while an amount of exceeding 50% by mass is also not preferable since hole transporting ability is impaired.

Specific examples of the preferable materials of the hole injecting layer and hole transport layer include layers containing pyrrole derivatives, carbazole derivatives, pyrazole derivatives, triazole derivatives, oxazole derivatives, oxadiazole derivatives, imidazole derivatives, polyaryl alkane derivatives, pyrazoline derivatives, pyrazolone derivatives, phenylenediamine derivatives, aryl amine derivatives, amino-substituted chalcone derivatives, styryl anthracene derivatives, fluorenone derivatives, hydrazone derivatives, stilbene derivatives, silazane derivatives, aromatic tertiary amine compounds, styrylamine compounds, aromatic dimethylidine compounds, porphyrin compounds, organic silane derivatives or carbon.

The thickness of a hole injecting layer or a hole transporting layer is not particularly limited, but is, from the standpoint of decreasing the driving voltage, improving the luminescent efficiency and improving the durability, preferably from 1 nm to 5 μm, more preferably from 5 nm to 1 μm, and still more preferably from 10 nm to 500 nm. A hole injecting layer or a hole transporting layer may be a single layer structure comprising one kind or two or more kinds of the aforementioned materials, or may also be a multilayer structure comprising a plurality of layers of the same composition or different compositions.

It is preferable for driving durability that Ip(HTL) of the hole transport layer is smaller than Ip(D) of the dopant contained in the luminescent layer when the carrier transporting layer adjacent to the luminescent layer is a hole transport layer.

Ip(HTL) in the hole transport layer can be measured by the method for measuring Ip to be described below.

The carrier mobility in the hole transport layer is usually in the range of 10⁻⁷ cm²·V⁻¹·s⁻¹ or more to 10−1 cm²·V⁻¹·s⁻¹ or less, and is preferable in the range of 10⁻⁵ cm²·V⁻¹·s⁻¹ or more to 10⁻¹ cm²·V⁻¹·s⁻¹ or less, more preferably 10⁻⁴ cm²·V⁻¹·s⁻¹ to 10⁻¹ cm²·V⁻¹·s⁻¹, and particularly preferably 10⁻³ cm²·V⁻¹·s⁻¹ to 10⁻¹ cm²·V⁻¹·s⁻¹, from the standpoint of luminous efficiency.

A value measured in the same way as used for measuring the carrier mobility in the luminescent layer is employed as the carrier mobility.

The carrier mobility in the hole transport layer is preferably larger than the carrier mobility in the luminescent layer from the standpoint of luminous efficiency.

(Electron Injecting Layer and Electron Transport Layer)

The electron injecting layer and electron transport layer have any one of functions for injecting the electrons from the cathode, for transporting the electrons and for blocking the holes injected from the anode.

The electron donating dopant introduced into the electron injecting layer or electron transport layer may have a property for donating electrons and for reducing organic compounds, and alkali metals such as Li, alkali earth metals such as Mg, transition metals including rare earth metals and reducing organic compounds are favorably used.

Metals with a work function of 4.2 eV or less may be favorably used, and specific examples thereof include Li, K, Na, Be, Mg, Ca, Sr, Ba, Y, Cs, La, Sm, Gd and Yb.

Specific examples of reducing organic compounds include nitrogen containing compounds, sulfur containing compounds, and phosphorus containing compounds and also materials described in JP-A Nos. 6-212153, 2000-196140, 2003-68468, 2003-229278, and 2004-342614.

One of these electron-donating dopant may be used alone, or a plurality of them may be used together. The amount of use of these electron-donating dopants is preferably in the range of 0.1% by mass to 99% by mass, more preferably 1.0% by mass to 80% by mass, and particularly preferably 2.0 to 70% by mass, although the amount differs depending on the kind of the material. An amount of use of less than 0.1% by mass relative to the amount of the material of the electron transport layer is not preferable for sufficiently manifesting the effect of the invention, while an amount of exceeding 99% by mass is also not preferable since electron transporting ability is impaired.

Specific examples of the electron injection layer and electron transport layer include the following materials: pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, anhydrides or imides of aromatic tetracarboxylic acid (examples of aromatic ring thereof include naphthalene and perylene), anhydrides or imides of aromatic dicarboxylic acid (examples of aromatic ring thereof include benzene and naphthalene), phthalocyanine, derivatives thereof (may form a condensed ring with another ring), and various metal complexes as represented by a metal complex of 8-quinolinol derivative, metal phthalocyanine and a metal complex with the ligand being benzoxazole or benzothiazole.

The electron injecting layer and the electron transporting layer are not particularly limited in their thickness but usually, from the standpoint of decreasing the driving voltage, improving the luminescent efficiency and improving the durability, the thickness is preferably from 1 nm to 5 μm, more preferably from 5 nm to 1 μm, and still more preferably from 10 nm to 500 nm.

The electron injecting layer and the electron transporting layer each may have a single-layer structure comprising one kind or two or more kinds of the above-described materials or may have a multilayer structure comprising a plurality of layers having the same composition or differing in composition.

When the carrier transporting layer adjacent to the light-emitting layer is an electron transporting layer, in view of driving durability, the Ea(ETL) of the electron transporting layer is preferably larger than the Ea(D) of the dopant contained in the light-emitting layer. It is more preferable that the relationship of Ea(ETL)−Ea(D)>0.1 eV is satisfied, and still more preferably, the relationship of Ea(ETL)−Ea(D)>0.2 eV is satisfied.

A value measured in the same way as the method for measuring Ea described below is used as Ea(ETL).

The carrier mobility in the electron transport layer is usually in the range of 10⁻⁷ cm²·V⁻¹·s⁻¹ or more to 10⁻¹ cm²·V⁻¹·s⁻¹ or less, and is preferably 10⁻⁵ cm²·V⁻¹·s⁻¹ or more to 10⁻¹ cm²·V⁻¹·s⁻¹ or less, more preferably 10⁻⁴ cm²·V⁻¹·s⁻¹ or more to 10⁻¹ cm²·V⁻¹·s⁻¹ or less, and particularly preferably 10⁻³ cm²·V⁻¹·s⁻¹ or more to 10⁻¹ cm²·V⁻¹·s⁻¹ or less from the standpoint of luminous efficiency.

It is preferable for driving durability that the carrier mobility in the electron transport layer is larger than the carrier mobility in the luminescent layer. The carrier mobility was measured in the same way as the method for measuring the hole mobility in the hole transport layer.

It is preferable for driving durability that the carrier mobility in the luminescent element of the invention satisfies the relation of (electron transport layer>hole transport layer)>luminescent layer.

(Light-Emitting Layer)

The light-emitting layer is a layer having a function of, when an electric field is applied, receiving a hole from the anode, hole injecting layer, hole transporting layer or hole transporting intermediate layer and receiving an electron from the cathode, electron injecting layer, electron transporting layer or electron transporting intermediate layer, thereby providing a site for the recombination of a hole and an electron to emit light.

The light-emitting layer for use in the present invention contains at least one luminescent dopant and a plurality of host compounds.

The light-emitting layer may be a single layer or two or more layers. Each of the two or more layers may emit light with different emission color. When the light-emitting element includes a plurality of light-emitting layers, each of the light emitting layers preferably contains at least one luminescent dopant and a plurality of host compounds.

While the luminescent dopant and the plurality of host compounds contained in the luminescent layer of the invention may be a combination of a fluorescent dopant and the plurality of host compounds capable of obtaining light emission (fluorescent emission) from singlet excitons, or a combination of a phosphorescent dopant and the plurality of host compounds capable of obtaining light emission (phosphorescent emission) from triplet excitons, among these, the combination of the phosphorescent dopant and the plurality of host compounds is preferable from the standpoint of luminous efficiency.

The luminescent layer according to the invention may contain a plurality of luminescent dopants for improving color purity and for expanding the emission wavelength region.

(Luminescent Dopant)

Any of the phosphorescent materials and fluorescent materials may be used as the luminescent dopant of the invention.

The luminescent dopant of the invention and the host compounds preferably satisfy the relations of 1.2 eV>ΔIP>0.2 eV and 1.2 eV>Ea>0.2 eV from the standpoint of driving durability.

<<Phosphorescent Dopant>>

Examples of the phosphorescent dopant in general include complexes containing a transition metal atom or a lanthanoid atom.

The transition metal atom is not particularly limited but preferred examples thereof include ruthenium, rhodium, palladium, tungsten, rhenium, osmium, iridium, gold, silver, copper and platinum. Among these, rhenium, iridium and platinum are more preferred and iridium and platinum are further more preferred.

Examples of the lanthanoid atom include lanthanum, cerium, praseodymium, neodymium, samarium, europium, gadolinium, terbium, dysprosium, holmium, erbium, thulium, ytterbium and lutecium. Among these lanthanoid atoms, neodymium, europium and gadolinium are preferred.

Examples of ligands of complexes include those described by G. Wilkinson et al, Comprehensive Coordination Chemistry, Pergamon Press, 1987; H. Yersin, Photochemistry and Photophysics of Coordination Compounds, Springer-Verlag, 1987; and Akio Yamamoto, Organometallic Chemistry—Basis and Applications, Shokabo, 1982.

Specific examples of the ligand include halogen ligands (preferably chlorine ligands), aromatic carbon ring ligands (with a carbon number of preferably 5 to 30, more preferably 6 to 30, further preferably 6 to 20 and particularly preferably 6 to 12; for example, cyclopentadienyl anion, benzene anion, naphthyl anion), nitrogen-containing heterocyclic ligands (with a carbon number of preferably 5 to 30, more preferably 6 to 30, further preferably 6 to 20 and particularly preferably 6 to 12; for example, phenylpyridine, benzoquinoline, quinolinol, bipyridyl and phenanthroline), diketone ligands (for example acetylacetone), carboxylic acid ligands (with a carbon number of preferably 2 to 30, more preferably 2 to 20, further preferably 2 to 16; for example, acetic acid ligands), alcoholate ligands (with a carbon number of preferably 1 to 30, more preferably 1 to 20, further preferably 6 to 20; for example, phenolate ligands), silyloxy ligands (with a carbon number of preferably 3 to 40, more preferably 3 to 30, further preferably 3 to 20; for example, trimethyl silyloxy ligands, dimethyl-tert-buthylsilyloxy ligands, triphenyl silyloxy ligands), carbon monoxide ligands, isonitrile ligands, cyano ligands, phosphorus ligands (with a carbon number of preferably 3 to 40, more preferably 3 to 30, further preferably 3 to 20 and particularly preferably 6 to 20; for example, triphenylphosphine ligands), thiolate ligands (with a carbon number of preferably 1 to 30, more preferably 1 to 20, further preferably 6 to 20; for example, phenylthiolate) and phosphineoxide ligands (with a carbon number of preferably 3 to 30, more preferably 8 to 30, further preferably 18 to 30; for example, triphenylphosphineoxide). The nitrogen-containing heterocyclic ligands are more preferable.

The complex may have one transition metal atom in the compound, or may be a so-called multi-nuclear complex having two or more transition metal atoms, or may simultaneously contain different kinds of metal atoms.

Of these phosphorescent dopants, specific examples of luminescent dopants include phosphorescent compounds described in U.S. Pat. Nos. 6,303,238B 1 and 6,097,147; International Publication Nos. 00/57676, 00/70655, 01/08230, 01/39234A2, 01/41512A1, 02/02714A2, 02/15645A1 and 02/44189A1; JP-A Nos. 2001-247859, 2002-302671,, 2002-117978, 2003-133074, 2002-235076, 2003-123982, 2002-170684, 2002-226495, 2002-234894, 2001-247859, 2001-298470, 2002-173674, 2002-203678, 2002-203679, 2004-357791; Japanese Patent Application Nos.2005-75340 and 2005-75341; and European Patent Application No. 1211257, the disclosures of which are incorporated by reference herein. Among these, the more preferable luminescent dopants are Ir complexes, Pt complexes, Cu complexes, Re complexes, W complexes, Rh complexes, Ru complexes, Pd complexes, Os complexes, Eu complexes, Tb complexes, Gd complexes, Dy complexes and Ce complexes. In particular, Ir complexes, Pt complexes and Re complexes are preferred, and Ir complexes, Pt complexes and Re complexes each containing at least one coordination mode of metal-carbon bond, metal-nitrogen bond, metal-oxygen bond and metal-sulfur bond are more preferred.

=Fluorescent Dopant=

Examples of the fluorescent dopant in general include benzoxazole, benzimidazole, benzothiazole, styrylbenzene, polyphenyl, diphenylbutadiene, tetraphenylbutadiene, naphthalimide, coumarin, pyran, perynone, oxadiazole, aldazine, pyralidine, cyclopentadiene, bisstyrylanthracene, quinacridone, pyrrolopyridine, thiadiazolopyridine, cyclopentadiene, styrylamine, aromatic dimethylidene compounds, condensed polycyclic aromatic compounds (e.g., anthracene, phenanthroline, pyrene, perylene, rubrene, pentacene), various metal complexes as represented by metal complexes of 8-quinolinol, pyrromethene complexes and rare earth complexes, polymer compounds such as polythiophene, polyphenylene and polyphenylene vinylene, organic silane, and derivatives thereof.

While specific examples of the luminescent dopant include those described below, they are not restricted thereto.

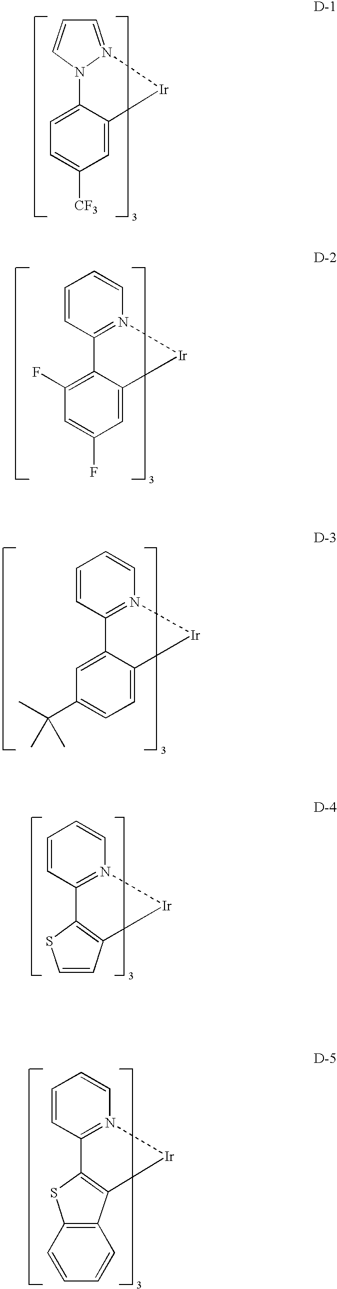

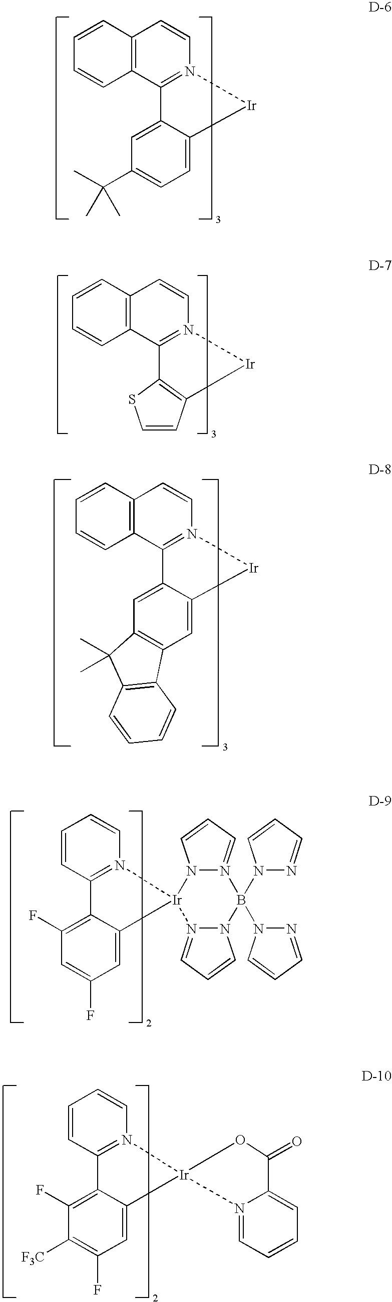

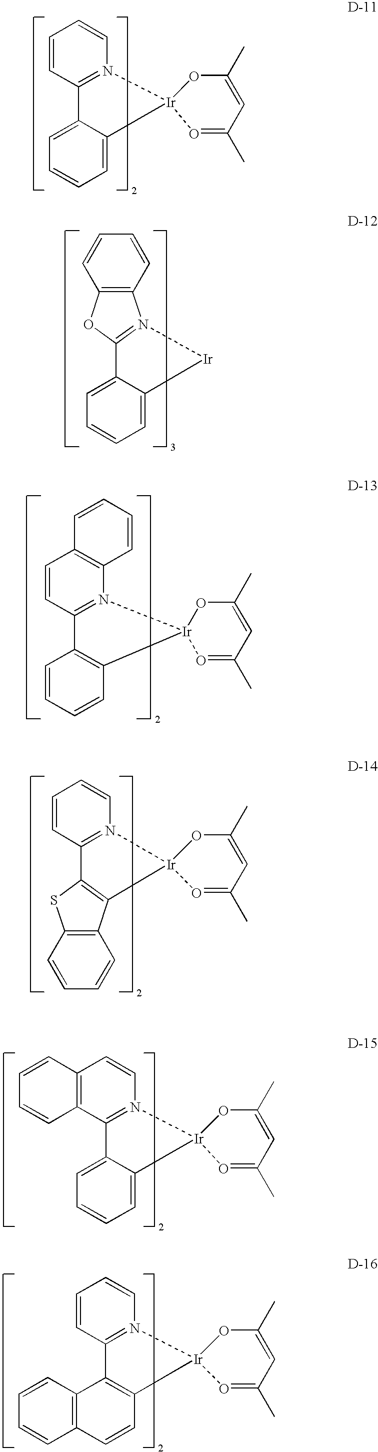

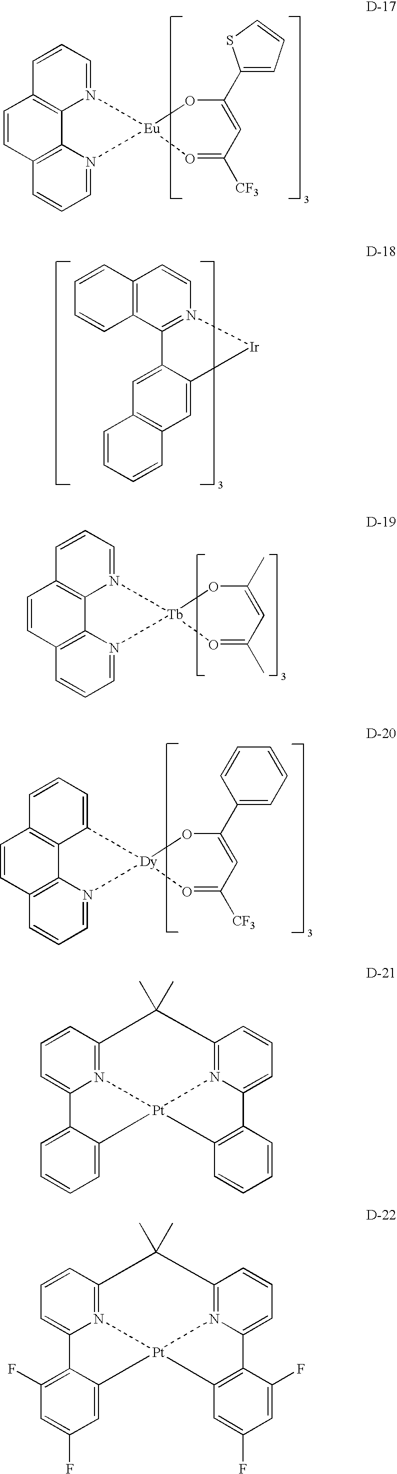

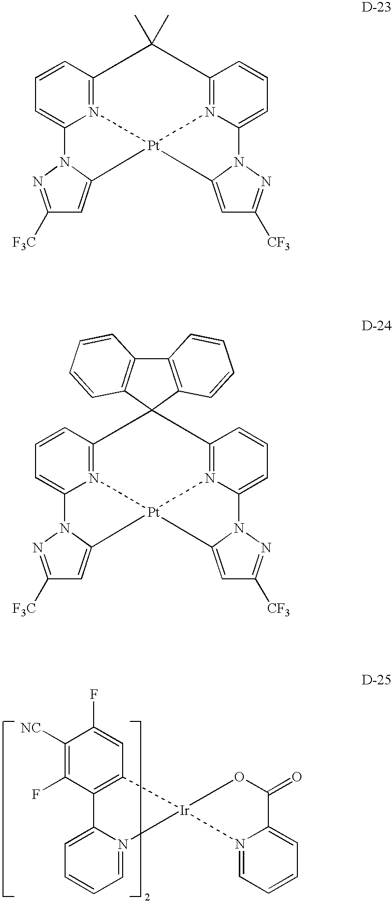

Among these compounds, D-2, D-3, D-4, D-5, D-6. D-7, D-8, D-9, D-10, D-11, D-12, D-13, D-14, D-15, D-16, D-21, D-22, D-23 , D-24 or D-25 is preferable, D-2, D-3, D-4, D-5, D-6. D-7, D-8, D-12, D-14, D-15, D-16 D-21, D-22, D-23 orD-24 is more preferable, and D-21, D-22, D-23 or D-24 is further preferable as the luminescent dopant used in the invention from the standpoint of luminous efficiency and durability.

While the luminescent layer usually contains the luminescent dopant in the range of 0.1% by mass to 30% by mass relative to the total mass of the compound that form the luminescent layer, the content is preferably 1% by mass to 15% by mass, more preferably 2% by mass to 12% by mass, from the standpoint of durability and luminous efficiency.

While the thickness of the luminescent layer is not particularly restricted, it is preferably that the thickness is in the range of 1 nm to 500 nm, and the thickness is more preferably in the range of 5 nm to 200 nm, further preferably 5 nm to 100 nm, from the standpoint of luminous efficiency.

(Host Material)

It is necessary that two or more kinds of the host materials are used in the luminescent layer.

A hole transporting host material (may be referred to a hole transporting host) excellent in transportability of the hole and an electron transporting host compound (may be referred to an electron transporting host) can be used as the host materials used in the invention.

(Hole Transporting Host)

The hole transporting host used in the organic layer of the invention preferably has an ionization potential Ip in the range of 5.1 eV or more to 6.3 eV or less, more preferably 5.4 eV or more to 6.1 eV or less, and further preferably 5.6 eV or more to 5.8 eV or less from the standpoint of improving durability and decreasing the driving voltage. Electron affinity Ea is preferably in the range of 1.2 eV or more to 3.1 eV or less, more preferably 1.4 eV or more to 3.0 eV or lass, and further preferably 1.8 eV or more to 2.8 eV or less from the standpoint of improving durability and decreasing the driving voltage.

Specific examples of such hole transporting host are following the materials.

The examples include pyrrole, carbazole, triazole, oxazole, oxadiazole, pyrazole, imidazole, polyaryl alkane, pyrazoline, pyrazolone, phenylenediamine, aryl amine, amino-substituted chalcone, styryl anthracene, fluorenone, hydrazone, stilbene, silazane, aromatic tertiary amine compounds, styrylamine compounds, aromatic dimethylidene-based compounds, porphyrin-based compounds, polysilane-based compounds, poly(N-vinylcarbazole), aniline-based copolymers, oligomers of conductive polymers such as thiophene oligomers and polythiophene, organic silane, carbon film and their derivatives.

Among these, the carbazole derivatives, aromatic tertiary amine compounds and thiophene derivatives are preferable, and compounds having a plurality of carbazole skeletons and/or aromatic tertiary amine skeletons in the molecule are particularly preferable.

While specific examples of the hole transporting host include the following compounds, they are not restricted thereto.

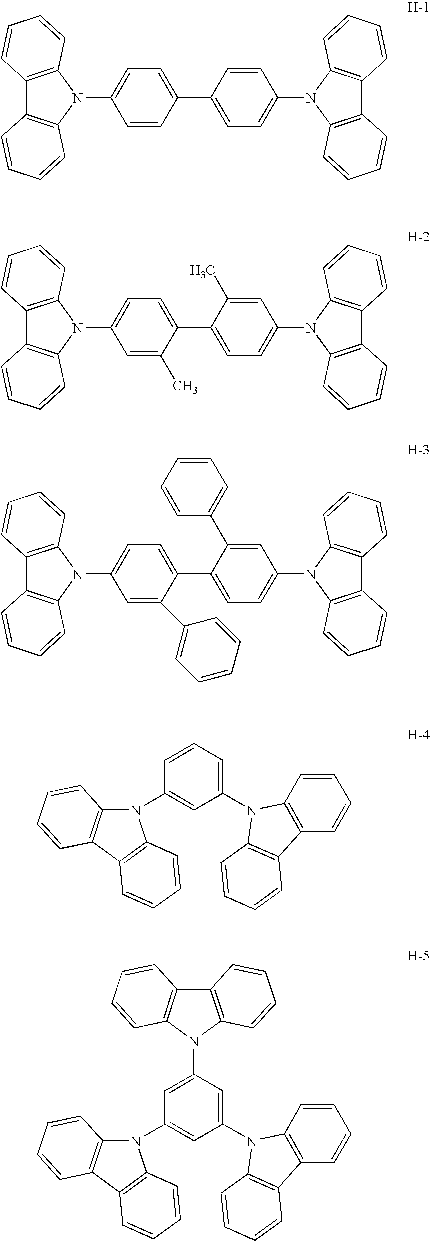

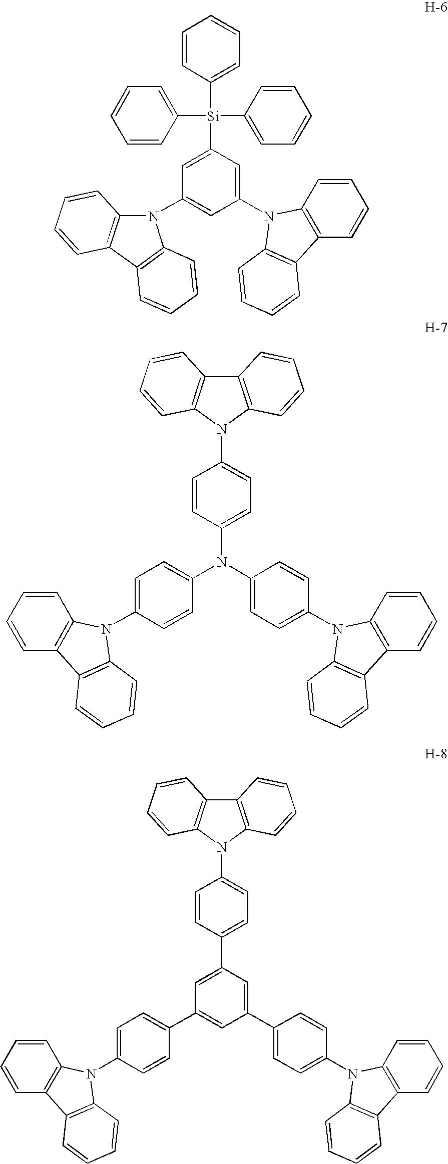

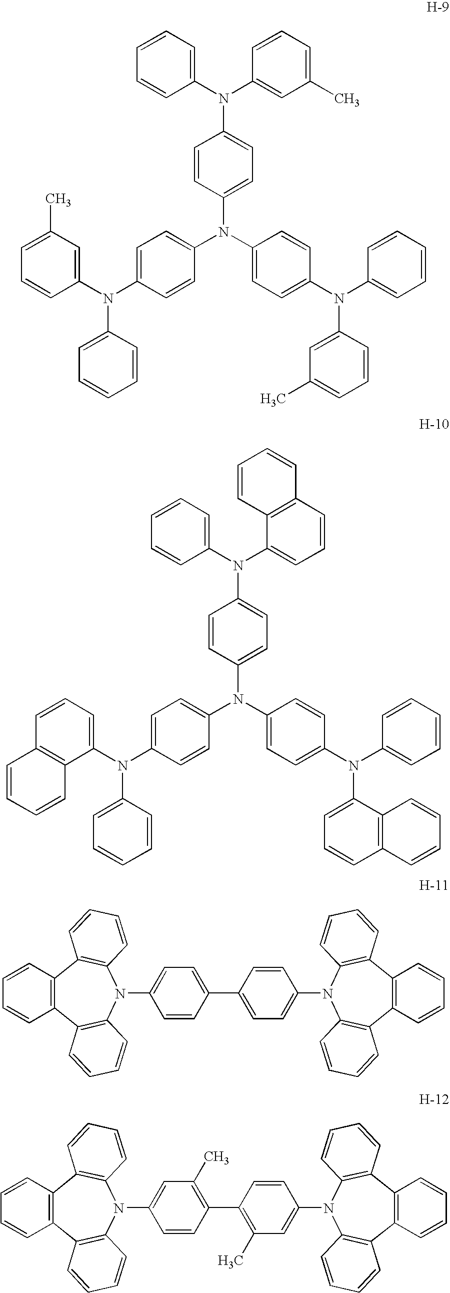

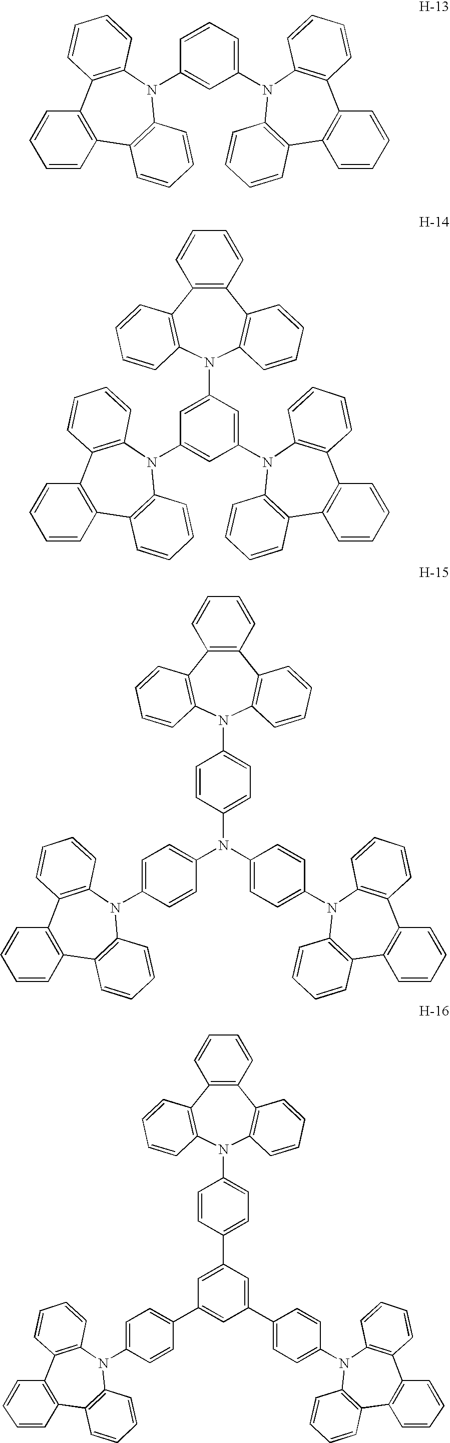

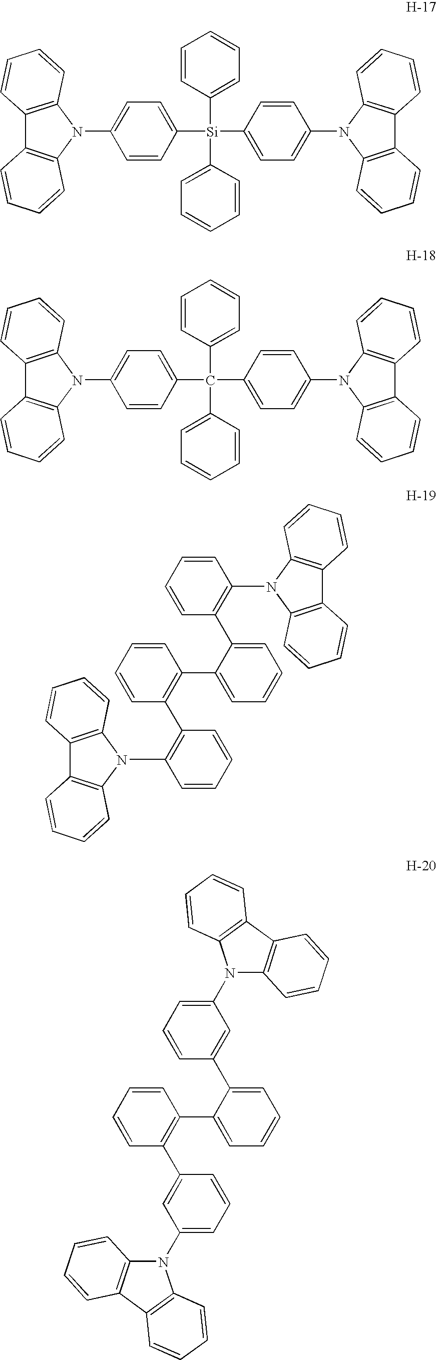

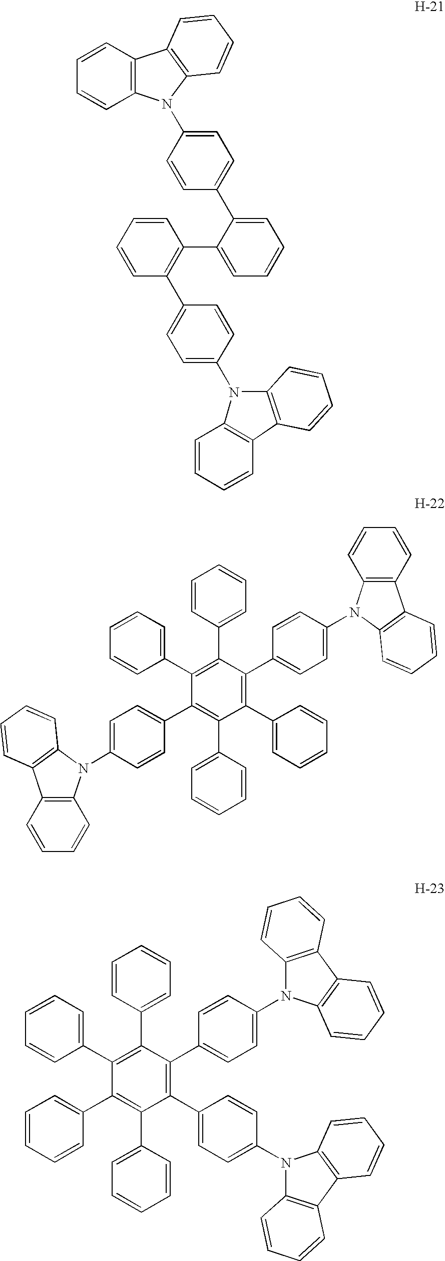

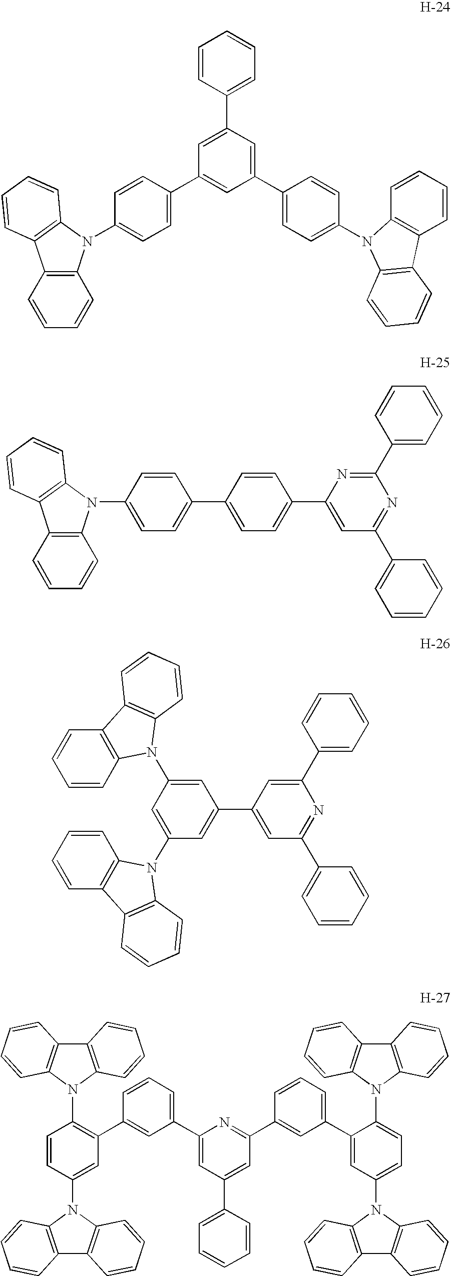

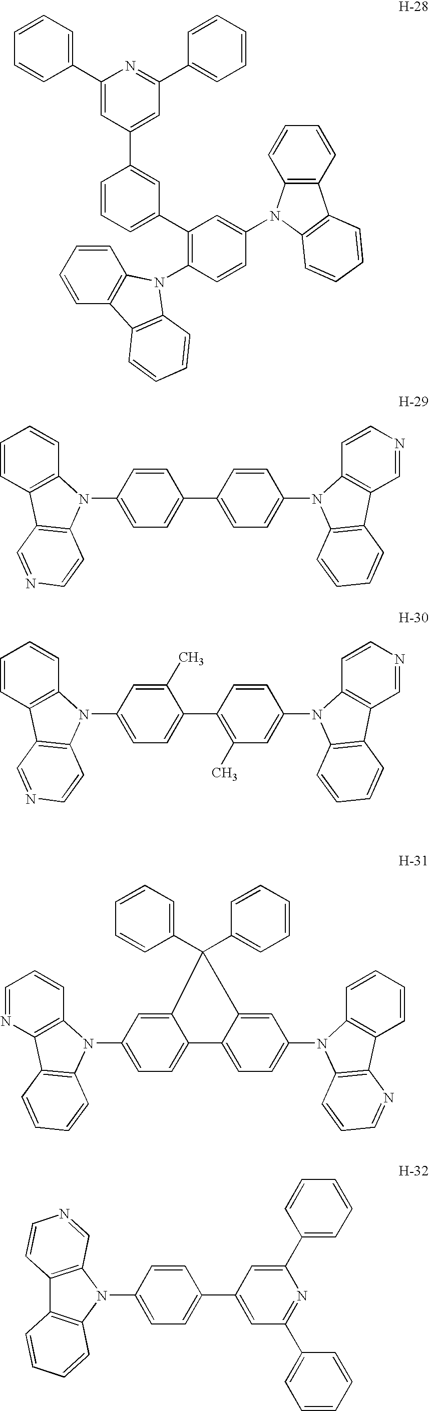

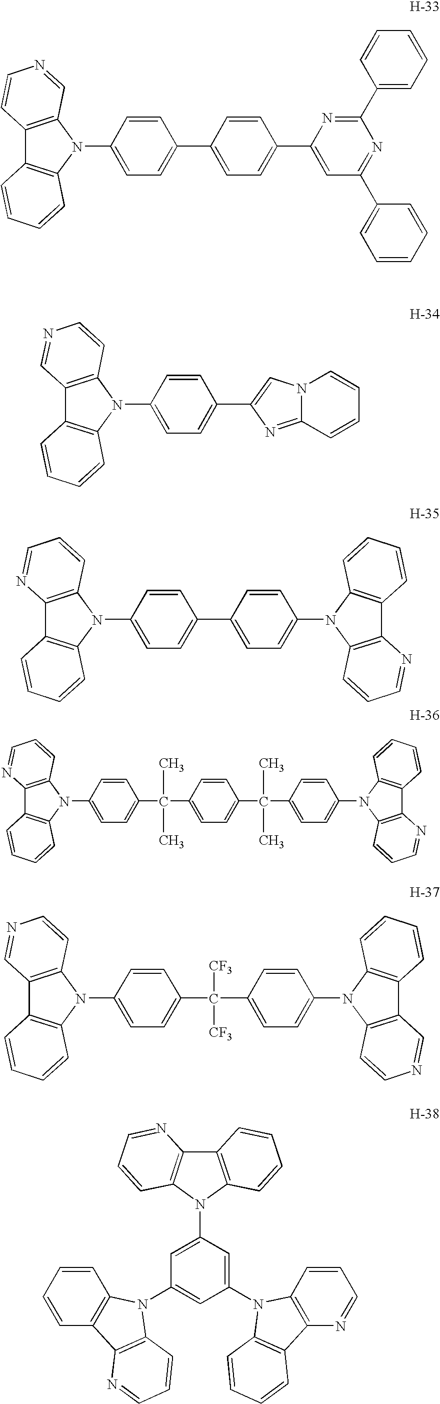

H-1 to H-21 are preferable, H-1 to H-18 are more preferable, and H-1, H-4 to H-6, H-12, H-14, H-17 or H-18 are further preferable as the hole transporting host.

(Electron Transporting Host)

The electron transporting host in the luminescent layer used in the invention preferably has electron affinity in the range of 2.5 eV or more to 3.5 eV or less, more preferably 2.6 eV or more to 3.2 eV or less, and further preferably 2.8 eV or more to 3.1 eV or less from the standpoint of improving durability and decreasing the driving voltage. The ionization potential is preferably in the range of 5.7 eV or more to to 7.5 eV or less, more preferably 5.8 eV or more to 7.0 eV or less, and further preferably 5.9 eV or more to 6.5 eV or less from the standpoint of improving durability and decreasing the driving voltage.

Specific examples of the electron transporting host include the following materials: pyridine, pyrimidine, triazine, imidazole, pyrazol,triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, anhydrides or imides of aromatic tetracarboxylic acid (examples of aromatic ring thereof include naphthalene and perylene), anhydrides or imides of aromatic dicarboxylic acid (examples of aromatic ring thereof include benzene and naphthalene), phthalocyanine, derivatives thereof (may form a condensed ring with another ring), and various metal complexes as represented by a metal complex of 8-quinolinol derivative, metal phthalocyanine and a metal complex with the ligand being benzoxazole or benzothiazole.

Examples of the electron transporting host are preferably metal complexes, azole derivatives (such as benzimidazole derivatives, imidazopyridine derivatives) and azine derivatives (such as pyridine derivatives pyrimidine derivatives and triazine derivatives), and among these the metal complex compounds are preferable among them from the standpoint of durability. More preferably, metal complex compound (A) has ligands comprising at least one nitrogen atom or oxygen atom coordinating to the metal.

While the metal ion in the metal complex is not particularly restricted, it is preferably beryllium ion, magnesium ion, aluminum ion, gallium ion, zinc ion, indium ion, tin ion, platinum ion or palladium ion, more preferably beryllium ion, aluminum ion, gallium ion, zinc ion, platinum ion or palladium ion, and further preferably aluminum ion, zinc ion or palladium ion.

While various known ligands are available as the ligand contained in the metal complex, examples of them include those described in H. Yersin, Photochemistry and Photophysics of Coordination Compound, Springer-Verlag Co., 1987, and Akio Yamamoto, Organometallic Chemistry—Bases and Application, Shokabo Co., 1982.

The ligand is preferably a nitrogen-containing heterocyclic ligand (may be a monodentate ligand or a bidentate or higher of ligands with a carbon number of preferably 1 to 30, more preferably 2 to 20, and particularly preferably 3 to 15). The ligand is preferably bidentate or higher to 6-dentate or lower. A mixed ligand of bidentate or higher to 6-dentate or lower is also preferable.

Examples of the ligand include azine ligands (for example pyridine ligand, bipyridyl ligands and terpyridine ligand), hydroxyphenyl anisole ligands (for example hydroxyphenyl benzimidazole ligands, hydroxyphenyl benzoxazole ligands, hydroxyphenyl imidazole ligands and hydroxyphenyl imidazopyridine ligands), alkoxy ligands (with a carbon number of preferably 1 to 30, more preferably 1 to 20, and particularly preferably 1 to 10; for example methoxy, ethoxy, butoxy and 2-ethylhexyloxy ligands), aryloxy ligands (with a carbon number of preferably 6 to 30, more preferably 6 to 20 and particularly preferably 6 to 12; for example phenyloxy, 1-naphthyloxy, 2-naphthyloxy, 2,4,6-trimethylphenyloxy and 4-biphenyloxy ligands),

heteroaryloxy ligands (with a carbon number of preferably 1 to 30, more preferably 1 to 20 and particularly preferably 1 to 12; for example pyridyloxy, pyradyloxy, pyrimidyloxy and quinolyloxy ligands), alkylthio ligands (with a carbon number of preferably 1 to 30, more preferably 1 to 20 and particularly preferably 1 to 12; for example methylthio and ethylthio ligands), arylthio ligands (with a carbon number of preferably 6 to 30, more preferably 6 to 20 and particularly preferably 6 to 12; for example phenylthio ligand), heteroarylthio ligands (with a carbon number of preferably 1 to 30, more preferably 1 to 20 and particularly preferably 1 to 12; for example pyridylthio, 2-benzimizolylthio, 2-benzoxazolylthio and 2-benzthiazolylthio ligands), siloxy ligands (with a carbon number of preferably 1 to 30, more preferably 3 to 25 and particularly preferably 6 to 20; for example triphenylsiloxy salt, triethoxysiloxy salt and triisopropylsiloxy salt ligands), aromatic hydrocarbon anion ligands (with a carbon number of preferably 6 to 30, more preferably 6 to 25 and particularly preferably 6 to 20; for example phenyl anion, naphthyl anion and anthranyl anion ligands), aromatic heterocyclic anion ligands (with a carbon number of preferably 1 to 30, more preferably 2 to 25 and particularly preferably 2 to 20; for example pyrrole anion, pyrazole anion, triazole anion, oxazole anion, benzoxyazole anion, thiazole anion, benzothiazole anion, thiophene anion and banzothiophene anion ligands) and indolenine anion ligands. The ligand is preferably the nitrogen-containing heterocyclic ligand, aryloxy ligand, heteroaryloxy ligand or siloxy ligand; and more preferably nitrogen-containing heterocyclic ligand, aryloxy ligand, siloxy ligand, aromatic hydrocarbon anion ligand or aromatic heterocyclic anion ligand.

Examples of the electron transporting host of the metal complex are those described in JP-A Nos. 2002-235076, 2004-214179, 2004-221062, 2004-221065, 2004-221068 and 2004-327313.

While the specific examples of the electron transporting host include the following compounds, they are not restricted thereto.

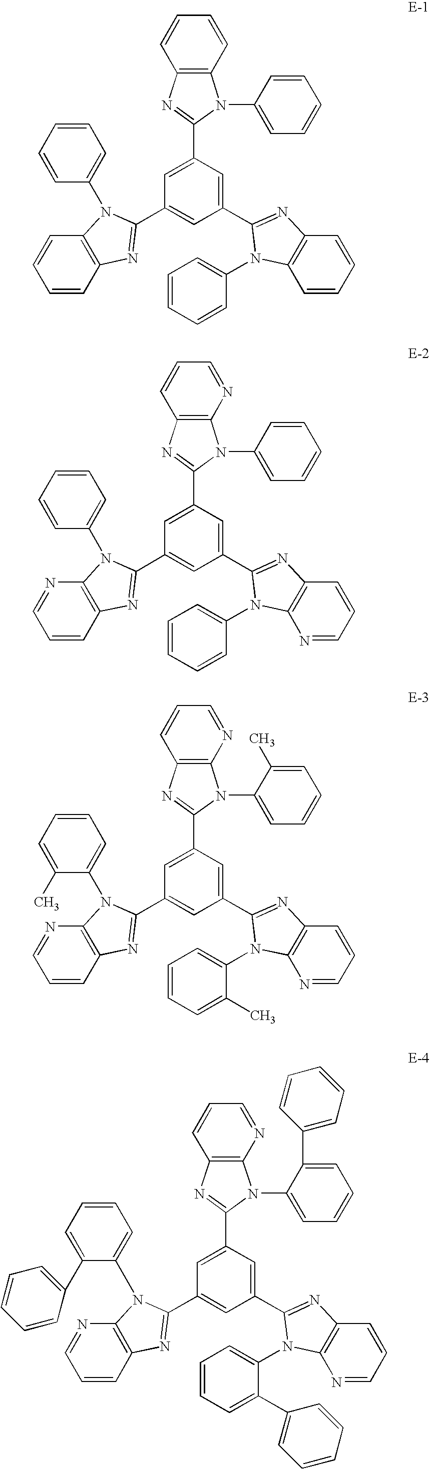

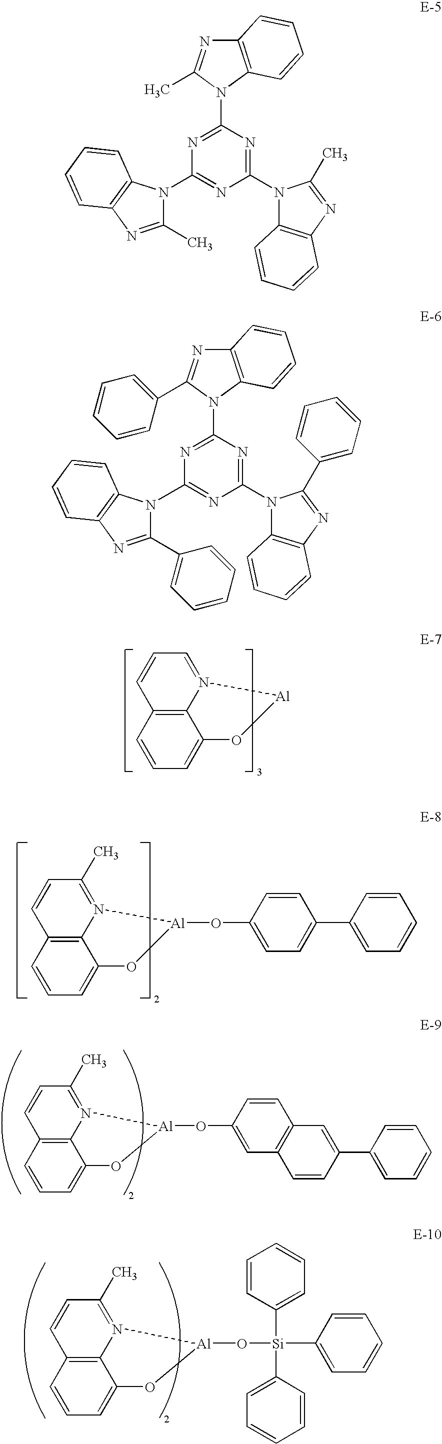

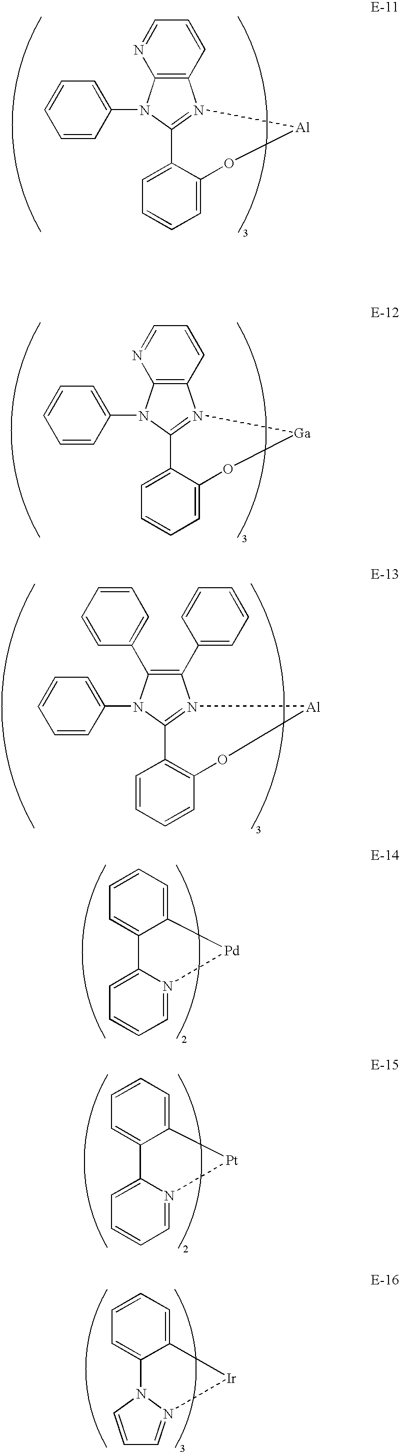

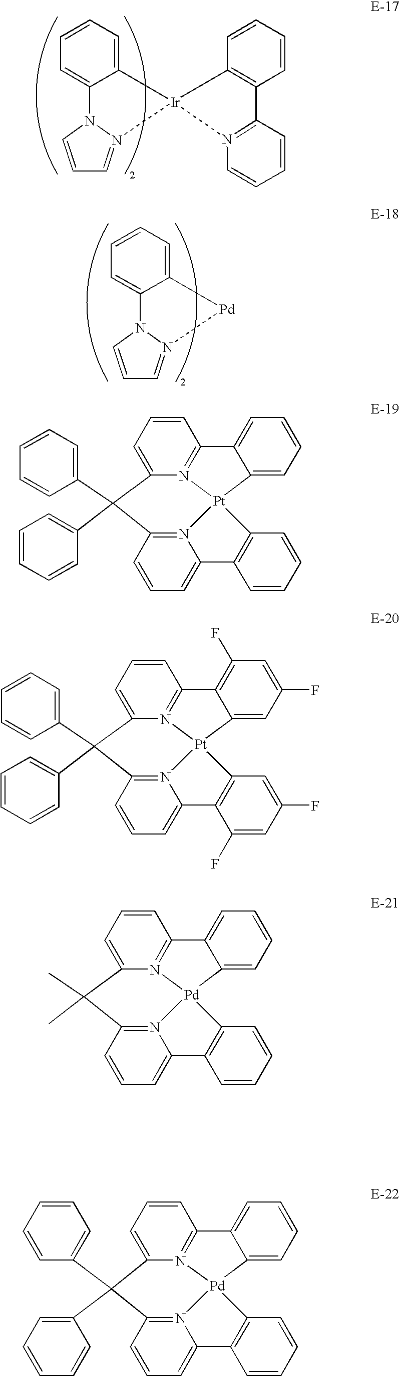

E-1 to E-6, E8, E-9 E-21 or E-22 is preferable, E-3, E-4, E-6, E-8, E-9, E-21 or E-22 are more preferable, and E-3, E-4, E-21 or E-22 are further preferable as the electron transporting host.

When the phosphorescent dopant is used as the luminescent dopant in the luminescent layer of the invention, the lowest triplet excitation energy T₁(D)of the phosphorescent dopant and the lowest (T₁(H)min)of the lowest triplet energy of the plurality of host compounds preferably satisfies the relation of T₁(H)min>T₁(D) from the standpoint of color purity, luminous efficiency and driving durability.

While the content of the plural host compounds of the invention are not particularly restricted, it is preferably in the range of 15% by mass or more to 85% by mass or less relative to the total mass of the compounds constituting the luminescent layer from the standpoint of luminous efficiency and driving voltage.

The carrier mobility in the luminescent layer is usually in the range of 10⁻⁷ cm²·V⁻¹·s⁻¹ or more to 10⁻¹ cm²·V⁻¹·s⁻¹ or less, and is preferably 10⁻⁶ cm²·V⁻¹·s⁻¹ or more to 10⁻¹ cm²·V⁻¹·s⁻¹ or less, further preferably 10⁻⁵ cm²·V⁻¹·s⁻¹ or more to 10⁻¹ cm²·V⁻¹·s⁻¹ or less, and particularly preferably 10⁻⁴ cm²·V⁻¹·s⁻¹ or more to 10⁻¹ cm²·V⁻¹·s⁻¹ or less from the standpoint of luminous efficiency.

It is preferable for luminous efficiency and driving durability that the carrier mobility in the luminous layer is smaller than the carrier mobility in the carrier transporting layer to be described below.

The carrier mobility was measured by Time-of-Flight method, and the value obtained was used as the carrier mobility.

(Hole Blocking Layer)

The hole blocking layer has a function for preventing the hole transported from the anode side to the luminescent layer from passing through the luminescent layer to the cathode side. The hole blocking layer may be provided as an organic compound layer adjoining to the luminescent layer at the cathode side.

While the hole blocking layer is not particularly restricted, specific examples of the material of the hole blocking layer include aluminum complexes such as BALq, triazole derivatives, pyridine derivatives, quinoline derivatives phenantroline derivatives and pyrazabole derivatives.

The thickness of the hole blocking layer is usually 50 nm or less, preferably in the range of 1 nm to 50 nm, and further preferably 5 nm to 40 nm in order to reduce the driving voltage.

(Anode)

The anode may usually serve as an electrode that supplies holes to the organic compound layer. The shape, structure, size and the like of the anode are not particularly limited and can be selected as appropriate from well known electrodes depending on the applications and purposes of a light-emitting element. As mentioned supra, the anode is usually formed as a transparent anode.

Examples of the material of the anode that are suitable include metals, alloys, metal oxides, electric conductive organic compounds and mixtures thereof, which preferably have a work function of 4.0 eV or more. Specific examples the material of the anode include electric conductive metal oxides such as tin oxides doped with antimony or fluorine (ATO, FTO), tin oxide, zinc oxide, indium oxide, indium tin oxide (ITO), and indium zinc oxide (IZO); metals such as gold, silver, chromium, and nickel; mixtures or laminates of these metals and electric conductive metal oxides; electric conductive inorganic substances such as copper iodide and copper sulfate; electric conductive organic materials such as polyaniline, polythiophene, and polypyrrole; laminates and the like of these and ITO. Among them, the material of the anode is preferably an electric conductive metal oxide, and more preferably ITO from the viewpoint of productivity, high electric conductivity, transparency and the like.

An anode can be formed on the above-described substrate in accordance with a method selected, as appropriate, in consideration of its suitability to the materials constituting the above-described anode, from wet methods such as the printing method and the coating method, physical methods such as the vacuum deposition method, the sputtering method and the ion plating method, chemical methods such as CVD and the plasma CVD method, and the like. For instance, when ITO is selected as the material of the anode, the formation of the anode can be carried out according to the direct current or high-frequency sputtering method, the vacuum deposition method, the ion plating method or the like.

In the organic electroluminescent element of the invention, the position of the anode to be formed is not particularly limited and can be selected as necessary depending on the applications or purposes of the light-emitting element. The anode may be formed on the entire surface of one surface of the substrate, or may also be formed on a portion thereof.

The patterning for forming the anode may be carried out by chemical etching such as photolithography, or may also be carried out by physical etching such as by means of a laser, or may also be carried out by vacuum deposition or sputtering after placing a mask, or may also be carried out by the lift-off method or the printing method.

The thickness of the anode can be selected, as appropriate, depending on the material constituting the above-described anode, cannot be specified unconditionally, may be usually from 10 nm to 50 μm, and is preferably from 50 nm to 20 μm.

The resistance value of the anode is preferably 103 Ω/sq or less, and more preferably 102 Ω/sq or less. When the anode is a transparent anode, the anode may be colorless transparent or may also be colored transparent. For the extraction of light emission from the anode side, the transmittance is preferably 60% or more, and more preferably 70% or more.

Additionally, transparent anodes which can be applied to the present invention are described in detail in “Tohmeidodenmaku No Shintenkai (Developments of Transparent Conductive Films)” edited by Yutaka Sawada, published by CMC (1999), the disclosure of which is incorporated by reference herein. When a plastic substrate of low heat resistance is used, ITO or IZO is employed, and a transparent anode that is film formed at a low temperature of 150° C. or less is preferable.

(Cathode)

The cathode may usually serve as an electrode that injects an electron to an organic compound layer. The shape, structure, size and the like are not particularly limited and can be selected as appropriate from well known electrodes depending on the applications and purposes of a light-emitting element.

Examples of the material constituting the cathode include metals, alloys, metal oxides, conductive compounds and mixtures thereof. These materials preferably have a work function of 4.5 eV or less. Specific examples of the material include alkali metals (such as Li, Na, K or Cs), alkali earth metals (such as Mg and Ca), gold, silver, lead, aluminum, sodium-potassium alloy, lithium-aluminum alloy, magnesium-silver alloy, indium and rare earth metals such as Ytterbium. While one of these materials may be used alone, at least two of them may be favorably used together from the standpoint of compatibility of stability and electron injecting ability.

Among these, alkali metals and alkali earth metals are preferable as the material constituting the cathode from the standpoint of electron injecting ability, and a material mainly comprising aluminum is preferable from the standpoint of storage stability.

The material mainly comprising aluminum refers to pure aluminum, or an alloy of aluminum and an alkali metal or an alkali earth metal in the range of 0.01% by mass to 10% by mass, or a mixture thereof (for example lithium-aluminum alloy and magnesium-aluminum alloy).

In addition, materials of the cathode are described in JP-A Nos. 2-15595 and 5-121172, the disclosures of which are incorporated by reference herein, and the materials described in these gazettes can also be applied to the invention.

Methods of forming the cathode are not particularly limited and can be carried out in accordance with well known methods. For instance, a cathode can be formed in accordance with a method selected, as appropriate, in consideration of its suitability to the materials constituting the above-described cathode, from wet methods such as the printing method and the coating method; physical methods such as the vacuum deposition method, the sputtering method and the ion plating method; chemical methods such as CVD and the plasma CVD method; and the like. For example, when metals and the like are selected as materials of the cathode, the formation can be carried out with one kind thereof or two or more kinds thereof at the same time or one by one in accordance with the sputtering method or the like.

The patterning for forming the cathode may be carried out by chemical etching such as photolithography, or may also be carried out by physical etching such as by means of a laser, or may also be carried out by vacuum deposition or sputtering after placing a mask, or may also be carried out by the lift-off method or the printing method.

In the invention, the position of a cathode to be formed is not particularly limited and may be formed on the entire organic compound layer, or may also be formed on a portion thereof.

Also, a dielectric layer with a thickness of 0.1 nm to 5 nm made of a fluoride or an oxide of an alkali metal or an alkali earth metal, or the like, may be inserted between the cathode and the organic compound layer. This dielectric layer can be considered to be a kind of electron injecting layer. The dielectric layer can be formed by, for example, the vacuum deposition method, the sputtering method, the ion plating method or the like.

While the thickness of the cathode can be appropriately selected depending on the material constituting the cathode and cannot be uniquely determined, it is usually in the range of about 10 nm to about 5 μm, preferably from about 50 nm to about 1 μm. The cathode may be either transparent or opaque. The transparent cathode can be formed by depositing the cathode material to be as thin as 1 nm to 10 nm followed by laminating a transparent conductive material such as ITO or IZO thereon.

(Substrate)

In the invention a substrate can be used. The substrate to be used in the invention is preferably a substrate that does not scatter or attenuate light emitted from an organic compound layer. Specific examples of the substrate include inorganic materials such as Yttria-stabilized Zirconia (YSZ) and glass; polyesters such as polyethylene terephthalate, polybutylene phthalate, and polyethylene naphthalate; and organic materials such as polystyrene, polycarbonate, polyether sulfone, polyallylate, polyimides, polycycloolefins, norbomene resin, and poly(chlorotrifluoroethylene).

When the substrate is made of glass, the glass is preferably no-alkali glass in order to reduce ions deriving from the glass. When the substrate is made of soda lime glass, the substrate is preferably coated with a barrier coating such as silica. When an organic material is used, the material is preferably excellent in heat resistance, dimension stability, solvent resistance, electric insulation and processability.

The shape, structure, size and the like of a substrate are not particularly limited and can be selected as appropriate depending on the applications, purposes and the like of a light-emitting element. In general, the shape is preferably board-shaped. The structure of the substrate may be a single-layer structure or may also be a laminated structure. The substrate may be fabricated with a single member or may also be formed with two or more members.

The substrate may be colorless transparent or may also be colored transparent, and is preferably colorless transparent in terms of no scattering or attenuation of the light emitted from the light-emitting layer.

A moisture penetration resistance layer (gas barrier layer) can be formed on the surface or the back (the aforementioned transparent electrode side) of the substrate.

Materials for the moisture penetration resistance layer (gas barrier layer) that are suitably used include inorganic substances such as silicon nitrate and silicon oxide. The moisture penetration resistance layer (gas barrier layer) can be formed by, for example, the radio-frequency (high-frequency) sputtering process or the like.

When a thermoplastic substrate is used, the substrate may be further equipped with a hard coat layer or an undercoat layer as required.

(Protective Layer)

In the invention, the whole organic EL element may be protected by a protective layer.

Any material may be contained in the protective layer insofar as it has the ability to prevent the intrusion of materials, such as water and oxygen, which promote the deterioration of the element, into the element.

Specific examples of the material of the protective layer include metals such as In, Sn, Pb, Au, Cu, Ag, Al, Ti and Ni; metal oxides such as MgO, SiO, SiO2, Al2O3, GeO, NiO, CaO, BaO, Fe2O3, Y2O3, and TiO2; metal nitrates such as SiNx and SiNxOy; metal fluorides such as MgF2, LiF, AlF3 and CaF2; polyethylene, polypropylene, polymethylmethacrylate, a polyimide, polyurea, polytetrafluoroethylene, polychlorotrifluoroethylene, polydichlorodifluoroethylene and copolymers of chlorotrifluoroethylene and dichlorodifluoroethylene; copolymers obtained by copolymerization of a monomer mixture including tetrafluoroethylene and at least one kind of comonomer; fluorine-containing copolymers having a ring structure on the copolymer backbone thereof; water absorptive materials having a water absorption of 1% or more; moisture-proof materials having a water absorption of 0.1% or less; and the like.

The method for forming the protective layer is not particularly restricted. Examples of the method available include a vacuum deposition method, a sputtering method, a reactive sputtering method, an MBE (molecular beam epitaxy) method, a cluster ion beam method, an ion plating method, a plasma polymerization method (high frequency excitation ion plating method), a plasma CVD method, a laser CVD method, a thermal CVD method, a gas source CVD method, a coating method, printing method or a transfer method.

(Sealing)

Furthermore, in the organic electroluminescent element of the invention, the entire element may be sealed with a sealing container. Also, the space between the sealing container and the luminescent element may be filled with a moisture absorbent or an inert liquid. The moisture absorbent is not particularly limited. Specific examples of the moisture absorbent include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, a molecular sieve, zeolite, magnesium oxide, and the like. An inert liquid is not particularly limited and the examples include paraffins, liquid paraffins, fluorine-based solvents such as perfluoroalkanes, perfluoroamines and perfluoroethers, chlorine-based solvents, and silicone oils.

In the organic electroluminescent element of the present invention, a DC (which, if desired, may contain an AC component) voltage (usually from 2 to 15 V) or a DC current is applied between the anode and the cathode, whereby light emission can be obtained.

In the present invention, the driving durability of the organic electroluminescent element can be measured by the brightness half-life time at a specific brightness. For example, a DC voltage is applied to the organic EL element to cause light emission by using the Source Measure Unit Model 2400 manufactured by KEITHLEY, a continuous driving test is performed under the condition of the initial brightness being 2,000 cd/m2, the time period until the brightness decreases to 1,000 cd/m2 is determined as the brightness half-life time T(½), and this brightness half-life time is compared with that of a conventional light-emitting element. The numerical value thus obtained is used as the brightness half-life time in the present invention.

The external quantum efficiency is also determined by “External quantum efficiency Φ=(internal quantum efficiency)×(light output efficacy)”. Since the threshold value of the internal quantum efficiency is about 25% and light output efficacy is about 20% in the organic EL element that takes advantage of fluorescence from an organic compound, the threshold value of the external quantum efficiency is calculated as about 5%.

The external quantum efficiency of the element is preferably 6% or more, particularly 12% or more, from the standpoint of decreasing the electric power consumption and increasing driving durability. The maximum value of the external quantum efficiency when the element is drove at 20° C., or the value of the external quantum efficiency at near 100 cd/m² to 300 cd/m² (preferably at 200 cd/m²) may be used as the above-mentioned quantum efficiency. In the invention, the EL element is made to emit a light by applying a direct current constant voltage to the element using a source measure unit (trade name: model 2400, manufactured by Toyo Corporation), luminance of the light is measured using a luminance meter (trade name: BM-8, manufactured by Topcon Corporation), and the external quantum efficiency at 200 cd/m² is calculated from the measured value.

The external quantum efficiency of the light-emitting element can also be calculated from the measured values of light emission brightness, light emission spectrum and current density, and the relative luminosity curve. More specifically, the number of electrons input can be calculated by using the current density value. Then, the light emission brightness can be converted into the number of photons which are emitted as light by integral computation using the light emission spectrum and relative luminosity curve (spectrum), and from the values obtained, the external quantum efficiency (%) can be calculated according to “(number of photons which are emitted as light/number of electrons input into element)×100”.

The driving of an organic electroluminescent element of the invention can utilize methods described in, for example, JP-A Nos. 2-148687, 6-301355, 5-29080, 7-134558, 8-234685 and 8-241047, Japanese Patent No. 2784615, and U.S. Pat. Nos. 5828429 and 602330, the disclosures of which are incorporated by reference herein.

(Application of Organic Electroluminescent Element of the Invention)

The organic electroluminescent element of the invention may be favorably used for a display element, display, back light, electrophotography, illumination light source, recording light source, exposing light source, read light source, sign, advertising display, interior illumination and light communication.

### EXAMPLE

While examples of the organic electroluminescent element of the invention are described below, the invention is by no means restricted to these examples.

### Example 1

1. Production of Organic Electroluminescent Element

An ITO glass substrate (manufactured by Geomatec Co. Ltd., surface resistivity; 10 Ω/sq) with a thickness of 0.5 mm and an area of 2.5 cm square was placed in a cleaning vessel, and was subjected to ultrasonic cleaning in 2-propanol followed by UV-ozone treatment for 30 minutes. The following layers were deposited in vacuum on this transparent anode. The vacuum deposition rate in the examples of the invention is 0.2 nm/second unless otherwise specified. The deposition rate was measured suing a quartz oscillator. Each film thickness described below is also measured using the quartz oscillator.

(Hole Injecting Layer)

2-TNATA was co-precipitated at a deposition rate of 0.5 nm/second so that the proportion of F4-TCQN (tetrafluoro-tetracyano quinodimethane) is 0.3% by mass relative to 2-TNATA. The thickness of the deposited film was 55 nm.

(Hole Transport Layer)

α-NPD was co-deposited on the hole injecting layer at a deposition rate of 0.5 nm/second so that the proportion of F4-TCQN is 0.3% by mass relative to α-NPD. The thickness of the deposited film was 5 nm.

(Hole Transporting Intermediate Layer)

CBP: film thickness; 10 nm (deposition rate: 0.3 nm/second)

(Luminescent Layer)

The deposition rates of CBP (hole transporting host) and ETM-1 (electron transporting host) were adjusted to 0.3 nm/second, respectively. CBP, ETM-1 and EM-I (phosphorescent dopant) were subjected to three component co-precipitation so that the proportion of EM-1 is 8% by mass relative to the total mass of the organic material in the luminescent layer. The film thickness of the luminescent layer was 20 nm.

(Electron transporting intermediate Layer)

ETM-1: film thickness 10 nm (deposition rate: 0.3 nm/second)

(Electron Transport Layer 1)

Balq: film thickness 10 nm (deposition rate: 0.3 nm/second)

(Electron Transport Layer 2)

Electron transport material ALq: film thickness 10 nm (deposition rate: 1 nm/second)

A patterned mask (a mask with a luminescent area of 2 mm×2 mm) was placed on the above-mentioned layers, and an electron injecting layer was formed by depositing lithium fluoride at a reposition rate of 0.1 nm/second. A cathode was formed by depositing metallic aluminum thereon.

The laminate prepared was placed in a glove box replaced with argon, and the laminate was hermetically sealed using a stainless sealing can and UV curable adhesive (trade name: XNR55 1 6HV, manufactured by Nagase Ciba Co.) to prepare the organic EL element of the element 1 of the present invention.

### Comparative Example 1

An comparative element 1 was prepared in the same way as the element in Example 1, except that 2-TNATA was deposited at a deposition rate of 0.5 nm/second to a thickness of 55 nm in place of the hole injecting layer of the element of Example 1, and α-NPD was deposited at a deposition rate of 0.5 nm/second to a thickness of 10 nm in place of the hole transport layer in Example 1.

### Example 2

The element 2 of present invention was prepared in the same way as the element in Example 1, except that the deposition conditions of the hole injecting layer, hole transport layer, electron transport layer 2 and electron transport layer 3 were changed from the conditions in Example 1 as follows.

(Hole Injecting Layer)

Copper phthalocyanine: film thickness 10 nm (deposition rate: 0.5 nm/second)

(Hole Transport Layer)

α-NPD: film thickness 30 nm (deposition rate: 0.3 nm/second)

(Electron Transport Layer 2)

Electron transport material ALq: film thickness 20 nm (deposition rate: 1 nm/second)

(Electron Transport Layer 3)

The deposition rate of the electron transport material ALQ was fixed at 10 nm/second, and ALq and metallic Li were co-precipitated so that the proportion of the metal is 3.0% by mass relative to the metal. The film thickness of electron transport layer 3 was 10 nm.

### Comparative Example 2

The comparative element 2 was prepared in the same way as the element in Example 2, except that the deposition condition of the electron transport layer 3 was changed as follows from the condition used for the element in Example 2.

(Electron Transport Layer 3)

Electron transport material ALq: film thickness 10 nm (deposition rate: 1 nm/second)

### Example 3

The element 3 of present invention was prepared in the same way as the element in Example 1, except that the deposition conditions of the electron transport layer 2 and electron transport layer 3 were changed as follows from the conditions of the element in Example 1.

(Electron Transport Layer 2)

Electron transport material ALq: film thickness 20 nm (deposition rate: 1 nm/second)

(Electron Transport Layer 3)

The deposition rate of the electron transport material ALq was fixed to 1.0 nm/second, and metallic Li and ALq were co-precipitated so that the proportion of metallic Li is 3.0% by mass relative to the mass of ALq. The film thickness of the electron transport layer 3 was 10 nm.

### Comparative Example 3

The comparative element 3 in Comparative Example 3 was prepared in the same way as the element in Example 3, except that each thickness of the hole transport layer and electron transport layer 2 was increased by 10 nm in place of eliminating the hole transporting intermediate layer and electron transporting intermediate layer provided in the element in Example 3.

### Examples 4 to 6 and Comparative Examples 4 to 6

The elements prepared in the same ways as the above-mentioned respective elements were obtained as the elements 4 to 6 and comparative elements 4 to 6, respectively, except that MCP was used in place of CBP used in the elements 1 to 3 of the present invention and comparative elements 1 to 3, and EM-3 was used in place of the luminescent dopant EM-1.

### Examples 7

The element in Example 7 was prepared in the same way as the element in Example 1, except that thickness of the hole transport layer was 10 nm

The structures of the compounds used for the above-mentioned luminescent elements are shown below. 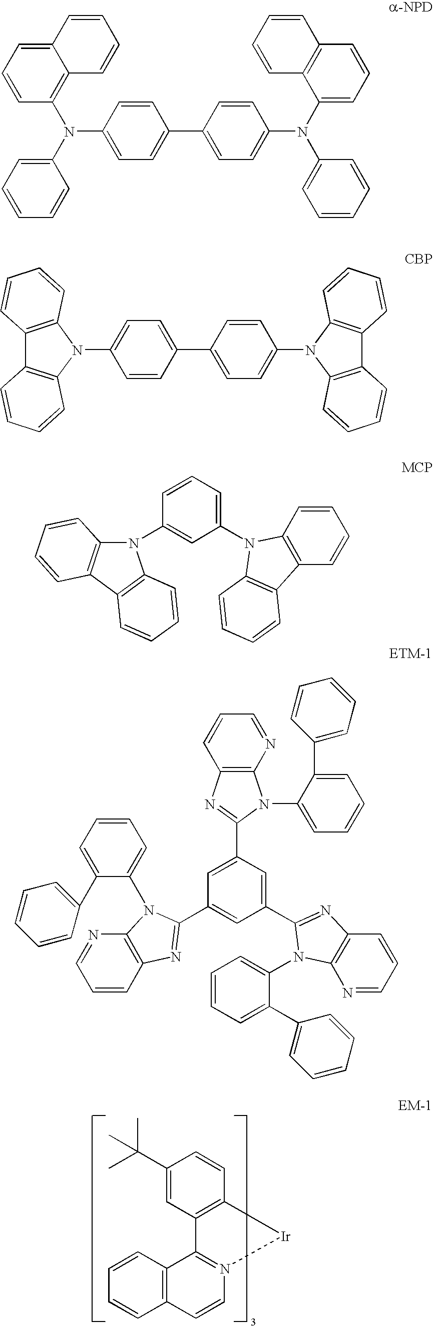 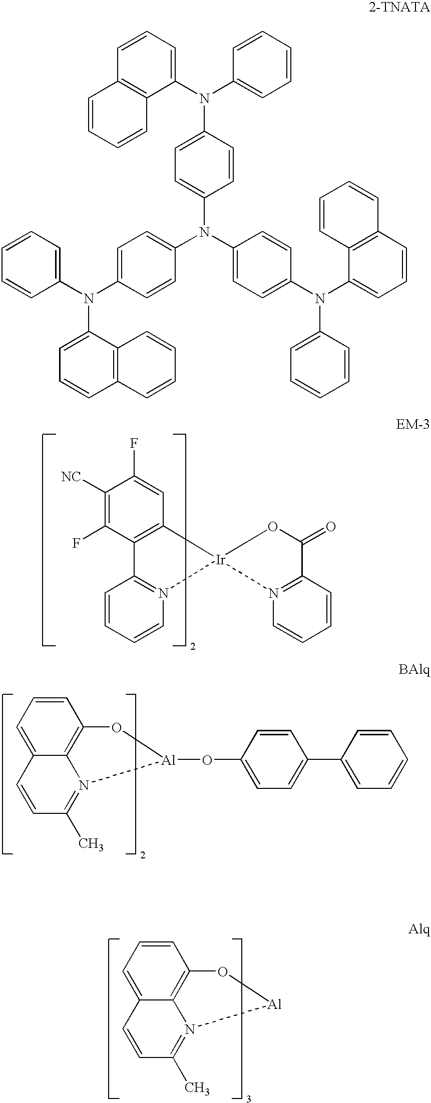
(Evaluation of Performance)
1. Evaluation of the Physical Properties of the Compound

The methods for measuring the ionization potential, electron affinity and T₁ energy of each compound used in the examples and the results of the measurement are shown in Table 1.

(1) Ionization Potential

Each compound used for the organic compound layer was deposited on a glass substrate so that the thickness of each layer is 50 nm. Ionization potential of this film was measured using a UV photoelectron analyzer AC-1 or AC-3 (trade name: manufactured by Riken Keiki Co. Ltd.) at room temperature under the atmospheric pressure.

(2) Electron Affinity

The UV-visible absorption spectrum of the film used for measuring the ionization potential was measured with UV 3100 spectrophotometer (trade name: manufactured by Shimadzu Corporation), and the excitation energy was determined from the energy at the long wavelength end of the absorption spectrum. Electron affinity was calculated from the excitation energy and ionization potential.

(3) T₁ Energy

The phosphorescence spectrum of the film used for measuring the ionization potential was measured at a temperature of 77 K using F4500 (trade name: manufactured by Hitachi Co. Ltd.) to determine the T₁ energy from the short wavelength end of the phosphorescence spectrum.

TABLE 1

| | Ionization | Electron | |
|---|---|---|---|
| | Potential | Affinity | T₁ energy |
| Compound | (eV) | (eV) | (kJ/mol) |
| CuPc | 5.1 | 3.4 | 230 or less |
| 2-TNATA | 5.1 | 2.2 | 226 |
| α-NPD | 5.4 | 2.4 | 230 or less |
| CBP | 5.9 | 2.5 | 251 |
| MCP | 5.9 | 2.3 | 278 |
| ETM-1 | 6.6 | 3.0 | 251 |
| EM-1 | 5.3 | 3.0 | 196 |
| EM-3 | 5.9 | 3.0 | 259 |
| BALq | 5.9 | 2.9 | 226 |
| ALq | 5.8 | 3.0 | 230 or less |

2. Evaluation of Organic Electroluminescent Element

The organic electroluminescent element obtained as above was evaluated as following methods.

(1) External Quantum Efficiency

The waveform of the luminescent element prepared was measured using multi-channel analyzer PMA-11 (trade name: manufactured by Hamamatsu Photonix K.K.). The wavelength of the emission peak was determined from the measured data. The external quantum efficiency is calculated from the waveform of the luminescence spectrum, and from the current and luminance (300 cd/m²) for the measurement. The results are shown in Table 2.

(2) Driving Durability Test

The element is allowed to emit a light by impressing a direct current voltage to the luminescent element using source measure unit model 2400 (trade name: manufactured by KEITHLEY Co.). The luminance was measured using luminance meter BM-8 (trade name: manufactured by Topcon Corporation) to calculate the external quantum efficiency at 300 cd/m².

Subsequently, the luminescent element was subjected to a continuous driving test under a condition of constant initial luminance. The time when the luminance is reduced to one half of the initial luminance was defined as a half-life (T) of luminance. The results are shown in Table 2 (the elements 1 to 3, and 7 of the present invention and the comparative elements 1 to 3 were evaluated at initial luminance of 2000 cd/m², and the elements 4 to 6 of the present invention and the comparative elements 4 to 6 were evaluated at initial luminance of 360 cd/m²).

(3) Driving Voltage

The luminescent element is allowed emit a light by impressing a direct current voltage to the element using source measure unit model 2400 (trade name: manufactured by KEITHLEY Co.). The voltage when the luminance is 300 cd/m² is measured using luminance meter BM-8 (trade name: manufactured by Topcon Corporation). The results are shown in Table 2.

TABLE 2

| | | External | | |
|---|---|---|---|---|
| | Driving | quantum | Half-Life of | |
| | Voltage | Efficiency | Luminescence | |
| Element | (V) | (%) | (Time) | Note |
| Element 1 of the | 5.8 | 14.6 | 4800 | Present |
| Invention | | | | Invention |
| Element 2 of the | 6.2 | 13.5 | 4600 | Present |
| Invention | | | | Invention |
| Element 3 of the | 5.5 | 15.5 | 3900 | Present |
| Invention | | | | Invention |
| Element 4 of the | 6.9 | 8.3 | 3100 | Present |
| Invention | | | | Invention |
| Element 5 of the | 7.5 | 8.5 | 2200 | Present |
| Invention | | | | Invention |
| Element 6 of the | 6.5 | 9.0 | 1800 | Present |
| Invention | | | | Invention |
| Element 7 of the | 6.0 | 15.2 | 5000 | Present |
| Invention | | | | Invention |
| Comparative | 9.0 | 6.3 | 2200 | Comparative |
| Element 1 | | | | Example |
| Comparative | 8.0 | 3.1 | 1800 | Comparative |
| Element 2 | | | | Example |
| Comparative | 7.5 | 8.3 | 1800 | Comparative |
| Element 3 | | | | Example |
| Comparative | 10.5 | 4.2 | 1200 | Comparative |
| Element 4 | | | | Example |
| Comparative | 9.5 | 5.3 | 1200 | Comparative |
| Element 5 | | | | Example |
| Comparative | 8.5 | 3.1 | 950 | Comparative |
| Element 6 | | | | Example |

The results in Table 2 show that the element of the invention is driven at low voltage with high luminous efficiency, and improves driving durability.

The invention provides an organic electroluminescent element having high luminous efficiency and driving durability. The invention also provides an organic electroluminescent element capable of driving at low voltage.

The invention also includes the following embodiments.

<1> An organic electroluminescent element including, interposed between a pair of electrodes, an organic layer including at least one luminescent layer and at least one charge transporting layer, wherein the organic electroluminescent element comprises:

(1) two or more kinds of host materials and at least one luminescent material included in the luminescent layer;

(2) at least one layer that is adjacent to the luminescent layer and includes a host material and substantially no luminescent material; and

(3) at least one charge transporting layer being doped with at least one of an electron-accepting compound or an electron-donating compound.

<2> The organic electroluminescent element of item <1>, wherein, at least one of the charge transporting layers is a hole transport layer disposed between the luminescent layer and an anode, and the hole transport layer is doped with a p-dopant of an electron-accepting compound.

<3>The organic electroluminescent element of items <1> or <2>, wherein at least one of the charge transporting layers is an electron transport layer disposed between the luminescent layer and a cathode, and the electron transport layer is doped with an n-dopant of an electron-donating compound.

<4> The organic electroluminescent element of any one of items <1> to <3>, wherein the layer including the host material and substantially no luminescent material is a hole transporting intermediate layer including a hole transporting host material and disposed on a surface of the luminescent layer that faces an anode.

<5> The organic electroluminescent element of any one of items <1> to <4>, wherein the layer including the host material and substantially no luminescent material is an electron transporting intermediate layer including an electron transporting host material and disposed on a surface of the luminescent layer that faces a cathode.

<6> The organic electroluminescent element of any one of items <1> to <5>, wherein the luminescent material is a phosphorescent material.

All publications, patent applications, and technical standards mentioned in this specification are herein incorporated by reference to the same extent as if such individual publication, patent application, or technical standard was specifically and individually indicated to be incorporated by reference.

It will be obvious to those having skill in the art that many changes may be made in the above-described details of the preferred embodiments of the present invention. The scope of the invention, therefore, should be determined by the following claims.

What is claimed is:

1. An organic electroluminescent element including, interposed between a pair of electrodes, an organic layer including at least one luminescent layer and at least one charge transporting layer, wherein the organic electroluminescent element comprises:
(1) two or more kinds of host materials and at least one luminescent material included in the luminescent layer;
(2) at least one layer that is adjacent to the luminescent layer and includes a host material and substantially no luminescent material; and
(3) at least one charge transporting layer being doped with at least one of an electron-accepting compound or an electron-donating compound.

2. The organic electroluminescent element of claim 1, wherein at least one of the charge transporting layers is a hole transport layer disposed between the luminescent layer and an anode, and the hole transport layer is doped with a p-dopant of an electron-accepting compound.

3. The organic electroluminescent element of claim 1, wherein at least one of the charge transporting layers is an electron transport layer disposed between the luminescent layer and a cathode, and the electron transport layer is doped with an n-dopant of an electron-donating compound.

4. The organic electroluminescent element of claim 1, wherein the layer including the host material and substantially no luminescent material is a hole transporting intermediate layer including a hole transporting host material and disposed on a surface of the luminescent layer that faces an anode.

5. The organic electroluminescent element of claim 1, wherein the layer including the host material and substantially no luminescent material is an electron transporting intermediate layer including an electron transporting host material and disposed on a surface of the luminescent layer that faces a cathode.

6. The organic electroluminescent element of claim 1, wherein the luminescent material is a phosphorescent material.

7. The organic electroluminescent element of claim 2, wherein the layer including the host material and substantially no luminescent material is a hole transporting intermediate layer containing a hole transporting host material and disposed on a surface of the luminescent layer facing an anode.

8. The organic electroluminescent element of claim 2, wherein the layer including the host material and substantially no luminescent material is an electron transporting intermediate layer including an electron transporting host material and disposed on a surface of the luminescent layer facing a cathode.

9. The organic electroluminescent element of claim 2, wherein the luminescent material is a phosphorescent material.

10. The organic electroluminescent element of claim 3, wherein the at least one of the charge transporting layers is a hole transport layer disposed between the luminescent layer and an anode, and the hole transport layer is doped with a p-dopant of an electron-accepting compound.

11. The organic electroluminescent element of claim 3, wherein the layer including the host material and substantially no luminescent material is a hole transporting intermediate layer containing a hole transporting host material and disposed on a surface of the luminescent layer facing an anode.

12. The organic electroluminescent element of claim 3, wherein the layer including the host material and substantially no luminescent material is an electron transporting intermediate layer containing an electron transporting host material and disposed on a surface of the luminescent layer facing an cathode.

13. The organic electroluminescent element of claim 3, wherein the luminescent material is a phosphorescent material.

14. The organic electroluminescent element of claim 4, wherein the layer including the host material and substantially no luminescent material is an electron transporting intermediate layer containing an electron transporting host material and disposed on a surface of the luminescent layer facing a cathode.

15. The organic electroluminescent element of claim 4, wherein the luminescent material is a phosphorescent material.

16. The organic electroluminescent element of claim 5, wherein the luminescent material is a phosphorescent material.

17. The organic electroluminescent element of claim 7, wherein the layer including the host material and substantially no luminescent material is a hole transporting intermediate layer containing a hole transporting host material and disposed on a surface of the luminescent layer facing an anode.

18. The organic electroluminescent element of claim 10, wherein the layer including the host material and substantially no luminescent material is a hole transporting intermediate layer containing a hole transporting host material and disposed on a surface of the luminescent layer facing an anode.

19. The organic electroluminescent element of claim 10, wherein the layer including the host material and substantially no luminescent material is an electron transporting intermediate layer containing an electron transporting host material and disposed on a surface of the luminescent layer facing a cathode.

20. The organic electroluminescent element according to claim 10, wherein the luminescent material is a phosphorescent material.
